(19) United States
(12) Patent Application Publication
(10) Pub. No.: US 2026/0171815 A1
(43) Pub. Date: Jun. 18, 2026

(54) CIRCUIT BOARD FOR BATTERY MONITORING SYSTEM, POWER SUPPLY SYSTEM, AND POWER SUPPLY CONTROL SYSTEM

(71) Applicant: DENSO CORPORATION, Kariya-city (JP)

(72) Inventor: Tatsuhiro NUMATA, Kariya-city (JP)

(73) Assignee: DENSO CORPORATION, Kariya-city (JP)

(21) Appl. No.: 19/533,871

(22) Filed: Feb. 9, 2026

Related U.S. Application Data
(63) Continuation of application No. PCT/JP2024/025627, filed on Jul. 17, 2024.

(30) Foreign Application Priority Data
Aug. 9, 2023 (JP) 2023-129796

(51) Int. Cl. H02J 7/52; H02J 7/82; H05K 1/18

(52) U.S. Cl. CPC H02J 7/52; H02J 7/82; H05K 1/18; H05K 2201/09027; H05K 2201/10098

(57) ABSTRACT

A circuit board is to be used for a battery monitoring system configured to monitor a battery condition of a battery unit. The circuit board includes: a wireless antenna; a wireless unit configured to perform wireless communication through the wireless antenna to transmit or receive the battery condition; and a connecting conductor configured to be connectable to an electrical path between the wireless unit and the wireless antenna and configured to allow an inspection terminal to be electrically connected thereto.

### CROSS-REFERENCE TO RELATED APPLICATIONS

This application is based on Japanese Patent Application No. 2023-129796 filed Aug. 9, 2023, the description of which is incorporated herein.

### TECHNICAL FIELD

The present disclosure relates to a circuit board for a battery monitoring system, a power supply system, and a power supply control system.

### BACKGROUND

In recent years, there have been battery monitoring systems, each of which transmit or receive a battery condition through wireless communication. Such a battery monitoring system is described, for example, in Patent Application Publication No. 2020-127318.

### SUMMARY

It is necessary in such a battery monitoring system to inspect whether a communication path is normal at a predetermined timing, such as during prototyping or shipment of the battery monitoring system. That is, it is necessary to inspect whether it is possible for such a battery monitoring system to normally transmit or receive the battery condition.

Wireless communication, however, undergoes trouble and problems more easily due to various factors such as external noise than wired communication. In view of these travel and problems, it is efficient to inspect, in addition to the inspection of, for example, an electrical path between a wireless IC and a wireless antenna, the antenna characteristics or other characteristics in advance.

The present disclosure has been derived in view of the circumstances. Specifically, the present disclosure seeks to provide a circuit board for a battery monitoring system, a power supply system, and a power supply control system, each of which is configured to be efficiently inspectable.

A circuit board to be used for a battery monitoring system configured to monitor a battery condition of a battery unit seeks to solve the above problems. The circuit board includes a wireless antenna, a wireless unit configured to perform wireless communication through the wireless antenna to transmit or receive the battery condition, and a connecting conductor configured to be connectable to an electrical path between the wireless unit and the wireless antenna and configured to allow an inspection terminal to be electrically connected thereto.

This makes it possible to input and output various signals to and from the middle of the electrical path through the connecting conductor. It is therefore possible to separate inspection targets and efficiently conduct inspections.

A power supply system, which seeks to solve the problems, includes a battery monitoring device including a first circuit board and configured to detect a battery condition of a battery unit, and a battery control device including a second circuit board and configured to wirelessly communicate with the battery monitoring device to obtain the battery condition detected by the battery monitoring device and manage the battery unit based on the battery condition. Each of the first circuit board and the second circuit board having opposing first and second ends. The power supply system includes a wireless antenna mounted to each of the first and second circuit boards, and a wireless unit mounted to each of the first and second circuit boards and configured to perform wireless communication through the wireless antenna to transmit or receive the battery condition. The power supply system includes a connecting conductor mounted to each of the first and second circuit boards and configured to be connectable to an electrical path between the wireless unit and the wireless antenna and configured to allow an inspection terminal to be electrically connected thereto. The power supply system includes a connector attached to one of the first and second ends of each of the first and second circuit boards. The connector of the second circuit board is configured to be connectable to an external device by wire. The wireless antenna of the second circuit board is disposed adjacent to the second end of the second circuit board of the battery control device.

This makes it possible to input and output various signals to and from the middle of the electrical path through the connecting conductor. It is therefore possible to separate inspection targets and efficiently conduct inspections.

In addition, the connector is attached to one of the first and second ends of each of the first and second circuit boards. The wireless antenna of the second circuit board is disposed adjacent to the second end of the second circuit board of the battery control device. This makes it possible to restrain the connector from obstructing radio waves from the wireless antenna.

A power supply control system, which seeks to solve the above problems, includes a battery unit, and a power supply system including a battery monitoring device and a battery control device. The battery monitoring device includes a first circuit board and is configured to detect a battery condition of the battery unit, and the battery control device includes a second circuit board and is configured to wirelessly communicate with the battery monitoring device to obtain the battery condition detected by the battery monitoring device and manage the battery unit based on the battery condition. The power supply control system includes a power converter configured to be connected to the power supply system. The power converter includes a switching element configured to convert power from the power supply system or switch between electrical connection and electrical disconnection of the power supply system. Each of the first circuit board and the second circuit board includes a wireless antenna mounted thereto, and a wireless unit mounted thereto and configured to perform wireless communication through the wireless antenna to transmit or receive the battery condition. Each of the first circuit board and the second circuit board includes a connecting conductor mounted thereto and configured to be connectable to an electrical path between the wireless unit and the wireless antenna and configured to allow an inspection terminal to be electrically connected to the connecting conductor. Each of the first circuit board and the second circuit board includes a front-end unit mounted thereto and disposed in the electrical path between the wireless unit and the wireless antenna. At least one of the first circuit board and the second circuit board is connected to a busbar configured to connect the battery unit and an electrical load. The power converter is connected to a ground member and configured to discharge noise generated by on/off control of the switching element to the ground member, thus decreasing intensity of noise flowing from the busbar to the front-end unit of the at least one of the first circuit board and the second circuit board to a value less than or equal to a current flowing through the front-end unit or a voltage across the front-end unit.

This makes it possible to input and output various signals to and from the middle of the electrical path through the connecting conductor. It is therefore possible to separate inspection targets and efficiently conduct inspections. In addition, it is possible to reduce noise coming through the busbar.

### BRIEF DESCRIPTION OF THE DRAWINGS

The object, other objects, features, and advantages of the present disclosure are made clearer by the following detailed description with reference to the accompanying drawings. In the drawings:

FIG. 1 is a schematic configuration diagram of a vehicle;

FIG. 2 is a block diagram illustrating a configuration of a battery pack;

FIG. 3 is a plan view for describing circuit arrangement in a battery monitoring device;

FIG. 4 is a plan view for describing circuit arrangement in a battery control device;

FIG. 5 is a diagram illustrating arrangement in the battery pack;

FIG. 6 is a diagram illustrating a configuration of a front-end circuit;

FIG. 7 is a plan view for describing a battery monitoring device according to a modification example;

FIG. 8 is a cross-sectional view for describing a battery monitoring device according to a modification example;

FIG. 9 is a plan view for describing a battery monitoring device according to a modification example;

FIG. 10 is a diagram illustrating a battery pack according to a modification example;

Each of FIGS. 11A and 11B is a cross-sectional view for describing a battery monitoring device according to a modification example;

FIG. 12 is a plan view for describing a battery monitoring device according to a modification example;

Each of FIGS. 13A and 13B is a diagram illustrating arrangement in a battery pack according to a modification example;

FIG. 14 is a plan view of a housing according to a modification example;

FIG. 15 is a side view of a housing according to a modification example; and

FIG. 16 is a plan view for describing circuit disposition in a battery control device according to a modification example.

### DESCRIPTION OF EMBODIMENTS

The following describes an embodiment of circuit boards, a power supply system, and a power supply control system usable for a battery monitoring system according to the present disclosure in detail with reference to the accompanying drawings. It should be noted that the same or corresponding portions in the drawings will be denoted with the same reference signs and the description thereof will not be repeated in principle. The following describes a typical embodiment applicable to a vehicle, but is applicable to other uses except for a vehicle.

### Overall Configuration of Vehicle

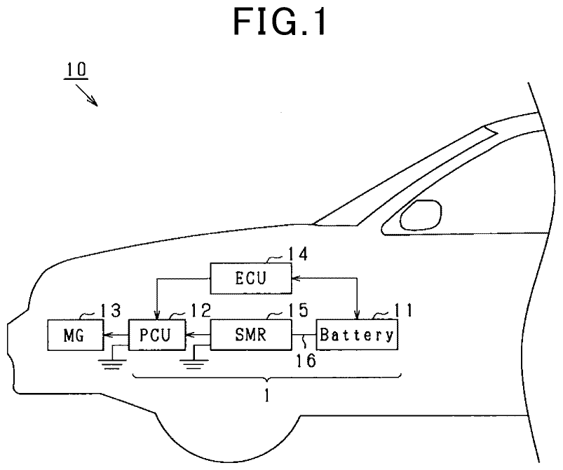

FIG. 1 is a diagram schematically illustrating the configuration of a vehicle 10. The vehicle 10 includes a battery pack 11 (illustrated as “Battery” in FIG. 1), a power control unit (referred to as “PCU (Power Control Unit)” 12 serving as a power converter, a motor 13 (illustrated as “MG” in FIG. 1) serving as an electrical load, and a vehicle ECU 14 (illustrated as “ECU” in FIG. 1). In the present embodiment, the battery pack 11 and the PCU 12 constitute a power supply control system 1. In addition, a busbar 16 serving as an electrical path between the PCU 12 and the battery pack 11 is provided in the power supply control system, and a relay switch 15 (illustrated as “SMR” in FIG. 1) is mounted on the busbar 16. The relay switch 15 is configured to switch between electrical connection and electrical disconnection of the busbar 16. The power supply control system 1 may include the relay switch 15. In addition, the power converter may include the relay switch 15.

The battery pack 11 is mounted to the vehicle 10 as a drive power supply of the vehicle 10. In FIG. 1, the battery pack 11 is installed in the engine compartment of the vehicle 10, but may be installed in another place such as the trunk compartment, a space under a seat, or a space under the floor. The vehicle 10 is an electric vehicle or a hybrid vehicle that travels using power stored in the battery pack 11.

The battery pack 11 includes an assembled battery 20 including a large number of battery cells 22 (unit batteries). The battery cells 22 are secondary batteries. For example, the battery cells 22 are lithium-ion batteries. The battery pack 11 stores, in the assembled battery 20, power for driving the motor 13. The battery pack 11 is capable of supplying the motor 13 with power through the PCU 12. In addition, when the motor 13 regenerates power, for example, at the time of braking the vehicle 10, the battery pack 11 is charged by the power generated by the motor 13 through the PCU 12. In the present embodiment, the assembled battery 20 corresponds to a battery unit.

In addition, the battery pack 11 is provided with battery monitoring devices 30 that each monitor the assembled battery 20 and a battery control device 40 that controls the battery monitoring devices 30. That is, the battery pack 11 according to the present embodiment corresponds to a power supply system including the assembled battery 20, the battery monitoring devices 30, and the battery control device 40. In addition, the battery monitoring devices 30 and the battery control device 40 correspond to a battery monitoring system 2. It should be noted that the configurations of the battery monitoring devices 30 and the battery control device 40 will be described below.

The PCU 12 converts power between the battery pack 11 and the motor 13 bidirectionally in accordance with a control signal from the vehicle ECU 14. The PCU 12 includes, for example, an inverter that drives the motor 13 and a converter that boosts a direct-current (DC) voltage supplied to the inverter to a voltage higher than or equal to an output voltage of the battery pack 11.

The motor 13 is an alternating-current (AC) rotating electrical machine. For example, the motor 13 is a three-phase AC synchronous electric motor having a rotor and one or more permanent magnets buried in the rotor. The motor 13 is driven by the PCU 12 to generate rotational driving force and the driving force generated by the motor 13 is transmitted to the driving wheels. Meanwhile, when the vehicle 10 is braked, the motor 13 operates as a generator and regenerates power. The power regenerated by the motor 13 is supplied to the battery pack 11 through the PCU 12 and stored in the assembled battery 20 in the battery pack 11.

The vehicle ECU 14 includes a CPU, a ROM, a RAM, an input/output port for inputting and outputting various signals, and other peripheral devices. The CPU loads programs stored in the ROM to the RAM and executes the programs. Each program stored in the ROM defines a corresponding process to be performed by the vehicle ECU 14.

As an example of a main process of the vehicle ECU 14, the vehicle ECU 14 receives information about, for example, the voltage across the assembled battery 20, the current flowing into or out of the assembled battery 20, and the SOC (State Of Charge) of the assembled battery 20 from the battery pack 11, and controls the PCU 12 based on the received information to thereby instruct driving of the the motor 13, and/or charging or discharging of the battery pack 11.

### Battery Pack

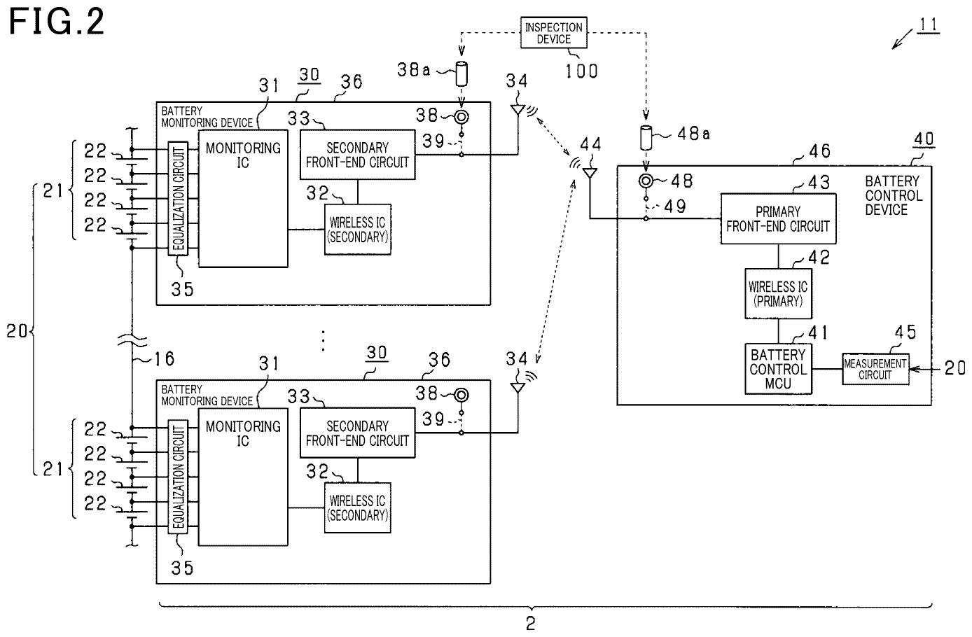

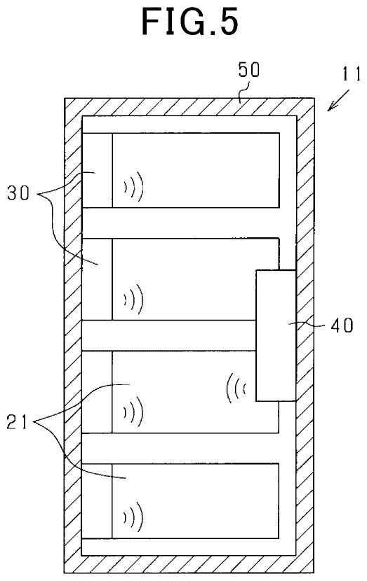

FIG. 2 is a diagram schematically illustrating the configuration of the battery pack 11. FIG. 5 is a schematic cross-sectional view of the arrangement of components included in the battery pack 11.

The battery pack 11 includes the assembled battery 20, the battery monitoring devices 30, the battery control device 40, and a housing 50 (illustrated in FIG. 5) that houses them. It should be noted that the battery control device 40 is housed in the housing 50 in the present embodiment, but may be disposed outside the housing 50. In addition, the battery pack 11 may not include such a housing, and the battery monitoring system 2 may be directly attached to any portion of the vehicle 10, such as the body frame of the vehicle 10. That is, the body frame of the vehicle 10 may be used to serves as a housing.

### Configuration of Assembled Battery

The assembled battery 20 includes a plurality of battery blocks 21, each of which may also be referred to as a battery stack or a battery module. The battery blocks 21 are connected in series and/or in parallel to constitute the assembled battery 20. Each of the battery blocks 21 includes the battery cells 22. Each of the battery cells 22 includes, for example, a lithium-ion secondary battery or a nickel-metal hydride secondary battery. It should be noted that the lithium-ion secondary battery is a secondary battery having lithium ions as a charge carrier. The lithium-ion secondary battery may include a so-called fully solid-state battery including a solid electrolyte in addition to a typical lithium-ion secondary battery including a liquid electrolyte. The battery cells 22 are connected in series and/or in parallel to constitute the battery block 21. The battery cells 22 may not be grouped into the battery blocks 21. That is, the battery cells 22 may be connected in series and/or in parallel to constitute the assembled battery 20.

### Battery Monitoring Device

Each of the battery monitoring devices 30 is also called satellite battery module (SBM: Satellite Battery Module).

The battery monitoring device 30 is provided for each of the battery blocks 21. That is, the battery monitoring device 30 is provided for the battery cells 22 included in each battery block 21.

As illustrated in FIG. 2, each of the battery monitoring devices 30 includes a monitoring IC 31 serving as a monitoring unit, a secondary wireless IC 32 serving as a wireless unit, a secondary front-end circuit 33 serving as a front-end unit, a secondary wireless antenna 34, an equalization circuit 35, a secondary board 36, and the like. Hereinafter, the secondary wireless IC 32, the secondary wireless antenna 34, and the secondary board 36 may be referred to as the “secondary unit 32”, the “secondary antenna 34”, and the “secondary board 36”, respectively.

The monitoring IC 31 is also called cell monitoring circuit and obtains battery information about each of the battery cells 22 included in the battery block 21. The battery information includes, for example, voltage information, temperature information, current information, and the like about each of the battery cells 22. It should be noted that a monitoring target of the battery monitoring device 30 may be each of the battery cells 22 or the whole of the assembled battery 20.

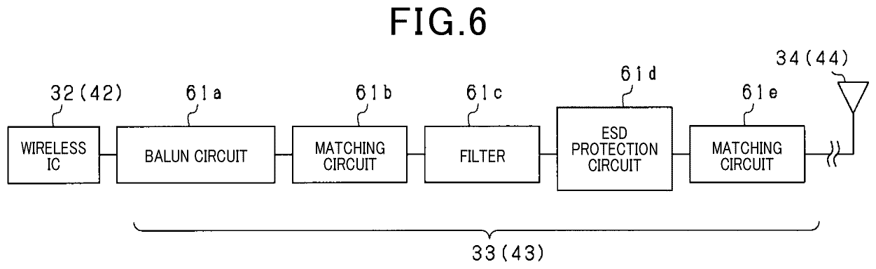

The secondary unit 32 is connected to the monitoring IC 31 by wire. The secondary unit 32 is connected to the secondary antenna 34 by wire through the secondary front-end circuit 33 serving as a front-end unit. The secondary front-end circuit 33 executes, for example, a demodulation process of extracting, from radio waves received by the secondary antenna 34, signals carried on the radio waves, and a modulation process of modulating signals onto radio waves for transmission from the secondary antenna 34 to the outside, and other processes. For example, as illustrated in FIG. 6, the secondary front-end circuit 33 includes a plurality of electronic components 61a to 61e, such as a balun circuit 61a, a matching circuit 61b, a filter 61c, an ESD protection circuit 61d, and a matching circuit 61e. It should be noted that FIG. 6 is an example of the secondary front-end circuit 33. The number of electronic components 61a to 61e, the types of the electronic components 61a to 61e, the arrangement of the electronic components 61a to 61e, and the like may be optionally changed.

The secondary unit 32 wirelessly transmits data (including a control signal and the like) received from the monitoring IC 31 through the secondary front-end circuit 33 and the secondary antenna 34. In addition, the secondary unit 32 transmits, to the monitoring IC 31, data received through the secondary antenna 34 and the secondary front-end circuit 33.

The equalization circuit 35 is a circuit for discharging each of the battery cells 22 and equalizing the voltages across the respective battery cells 22 in accordance with an instruction from the monitoring IC 31 or the battery control device 40.

The secondary board 36 is provided with these electronic components (such as the monitoring IC 31, the secondary unit 32, the secondary front-end circuit 33, the secondary antenna 34, and the equalization circuit 35) mounted thereto. The secondary board 36 is housed and fixed in the housing 50 as the battery monitoring device 30.

### Battery Control Device

The battery control device 40 is also called battery ECU or BMU (Battery Management Unit). The battery control device 40 is configured to be wirelessly communicable with each of the battery monitoring devices 30.

In detail, the battery control device 40 includes a battery control MCU 41 serving as a battery control unit, a primary wireless IC 42 serving as a wireless unit, a primary front-end circuit 43 serving as a front-end unit, a primary wireless antenna 44, a measurement circuit 45 serving as a measurement unit, a primary circuit board 46, and the like as illustrated in FIG. 2. Hereinafter, the primary wireless IC 42, the primary wireless antenna 44, and the primary circuit board 46 may be referred to as the “primary unit 42”, the “primary antenna 44”, and the “primary board 46”, respectively.

The battery control MCU 41 is comprised of an MCU (Micro Controller Unit) including a CPU, a ROM, a RAM, an input/output interface, and other peripheral devices. The CPU of the battery control MCU 41 loads programs stored in the ROM to the RAM and executes the programs. Each program stored in the ROM defines a corresponding process related to battery control.

As an example of a main process, the battery control MCU 41 instructs each of the battery monitoring devices 30 to obtain the battery information about the battery cells 22 monitored thereby and transmit the obtained battery information. In addition, the battery control MCU 41 monitors the assembled battery 20, the battery blocks 21, and the battery cells 22 in accordance with the battery information received from the battery monitoring device 30. Then, the battery control MCU 41 controls the relay switch 15 (power converter) that switches between (i) electrical connection of the assembled battery 20 to the PCU 12 and the motor 13 and (ii) electrical disconnection of the assembled battery 20 to the PCU 12 and the motor 13 in accordance with, for example, a result of the monitoring.

Additionally, the battery control MCU 41 optionally transmits an equalization signal that equalizes the voltages of the respective battery cells 22.

It should be noted that the vehicle ECU 14 of the present embodiment instructs the PCU 12 to perform control of charging discharging of the assembled battery 20, but the battery control MCU 41 may be configured to be capable of instructing the PCU 12 to perform control of charging discharging of the assembled battery 20. As described above, the battery control MCU 41 manages the assembled battery 20, the battery blocks 21, and the battery cells 22.

The primary unit 42 is connected to the battery control MCU 41 by wire. The primary unit 42 is connected to the primary antenna 44 by wire through the primary front-end circuit 43 serving as a front-end unit. Like the secondary front-end circuit 33, the primary front-end circuit 43 executes, for example, a demodulation process, a modulation process, and other processes. As illustrated in FIG. 6, the primary front-end circuit 43 includes the electronic components 61a to 61e.

The primary unit 42 wirelessly transmits data received from the battery control MCU 41 through the primary front-end circuit 43 and the primary antenna 44. In addition, the primary unit 42 transmits, to the battery control MCU 41, data received through the primary antenna 44 and the primary front-end circuit 43.

The measurement circuit 45 is a circuit that is connected between the positive and negative terminals of the assembled battery 20 and measures an inter-terminal voltage across the assembled battery 20, i.e., a total voltage of the batter cells 22, electric leakage, and other parameters. It should be noted that the measurement circuit 45 may measure the voltages of the battery blocks 21.

To the primary board 46, these electronic components (such as the battery control MCU 41, the primary unit 42, the primary front-end circuit 43, the primary antenna 44, and the measurement circuit 45) are mounted. The primary board 46 is housed and fixed in the housing 50 as the battery control device 40.

### Housing

The housing 50 is formed of an electrical conductor such as metal. The housing 50 is formed in the shape of a metal box. The housing 50 has a substantially rectangular solid shape. It should be noted that the housing 50 may be formed of an electrically non-conductive member such as resin. The housing 50 houses the assembled battery 20, the battery monitoring devices 30, and the battery control device 40.

It is necessary to inspect whether the battery control device 40 and the battery monitoring devices 30 operate normally at a predetermined timing, such as during prototyping of the battery pack 11. In wireless communication, inspections not performed in wired communication, such as inspection of antenna characteristics, are executed. For this reason, it is considered efficient to perform the inspection for each of components (or configurations) of each of the battery control device 40 and the battery monitoring devices 30. Accordingly, each of the battery control device 40 and the battery monitoring devices 30 is configured to enable inspection of each component thereof, which will be described below.

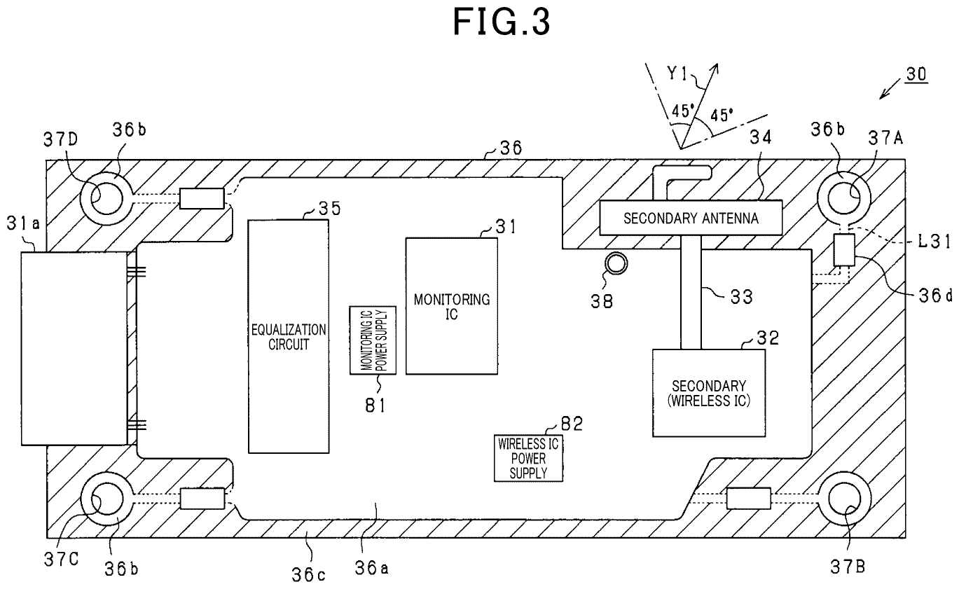

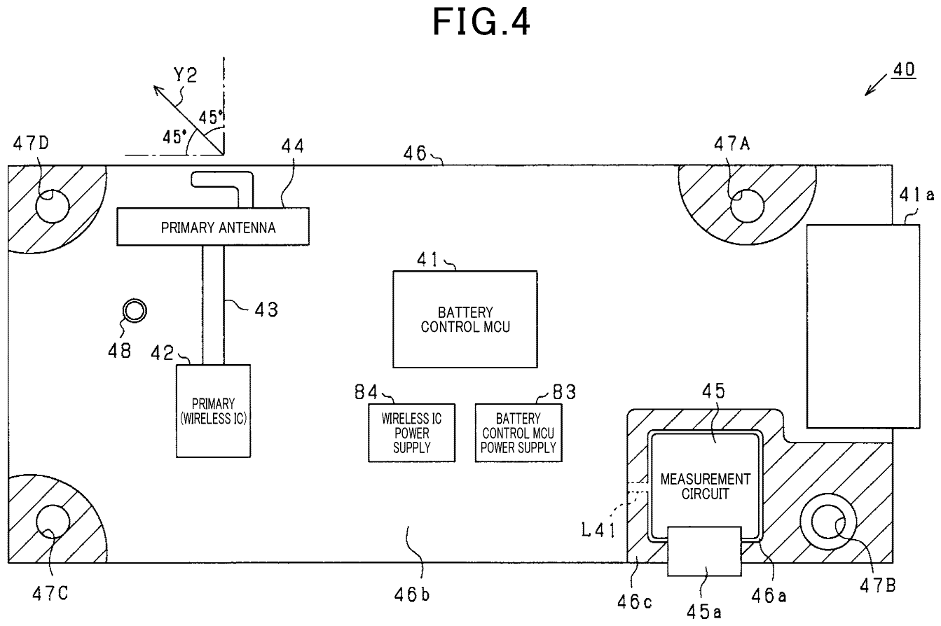

FIG. 3 is a plan view of the secondary board 36 in which electronic components constituting the battery monitoring device 30 and the arrangement of the electronic components on the secondary board 36 are schematically illustrated. FIG. 4 is a plan view of the primary board 46 in which electronic components included in the battery control device 40 and the arrangement thereof on the primary board 46 are schematically illustrated.

### Shape and Circuit Arrangement of Secondary Board

As illustrated in FIG. 3, the secondary board 36 has a horizontally long rectangular shape. The secondary board 36 has formed therethrough circular holes 37A to 37D, which are disposed close to the respective corners of the secondary board 36. The circular holes 37A to 37D serve as fastening members for fastening of the secondary board 36 to the housing 50.

In FIG. 3, predetermined electronic components included in the battery monitoring device 30, such as the monitoring IC 31, a monitoring IC power supply 81, and a wireless IC power supply 82, are mounted generally in a central region of a front surface of the secondary board 36. Predetermined electronic components included in the battery monitoring device 30, such as the equalization circuit 35, are mounted generally in a left region of the front surface of the secondary board 36. Predetermined electronic components, such as the secondary unit 32, the secondary front-end circuit 33, and the secondary antenna 34, are mounted generally in a right region of the secondary board 36.

In addition, in FIG. 3, a connector 31a included in the battery monitoring device 30, which is connected to the corresponding battery cells 22, is attached to the left end of the secondary board 36. The monitoring IC 31 is connected to the corresponding battery cells 22 through the connector 31a and configured to be capable of detecting the battery condition (battery information) of each of the corresponding battery cells 22.

It should be noted that the secondary board 36 is a printed board and has an unillustrated conductor pattern (wiring pattern) laid out thereon. The electronic components are connected to each other by the conductor pattern. In addition, although not illustrated, electronic components included in the battery monitoring device 30 other than the electronic components described above are also mounted to the secondary board 36. The electronic components mounted to the secondary board 36 include, for example, various electronic circuits and various circuit components (such as one or more capacitors, one or more switching elements, and one or more resistors).

In addition, the monitoring IC power supply 81 and the wireless IC power supply 82 are each a power converter serving as an electronic component that converts power supplied from a battery (such as the assembled battery 20 serving as a main machine battery) and supplies the converted power to the monitoring IC 31 and the secondary unit 32.

As illustrated in FIG. 2, the secondary front-end circuit 33 is disposed in the electrical path between the secondary unit 32 and the secondary antenna 34. An inspection land 38 is mounted to the secondary board 36 and configured to be connectable to the electrical path extending from the secondary front-end circuit 33 to the secondary antenna 34.

The inspection land 38 is an annular copper foil portion, which serves as a connecting conductor, provided around a circular hole that is formed through the secondary board 36. As illustrated in FIG. 2, a pin-shaped inspection terminal 38a is disposed in the inspection land 38 so as to be electrically connected to the inspection land 38. It should be noted that, as the inspection terminal 38a, a pin-shaped terminal is schematically described in the present embodiment, but the inspection terminal 38a may have any shape.

Additionally, it may be optionally changed how to connect the inspection land 38 and the inspection terminal 38a as long as the inspection land 38 and the inspection terminal 38a are electrically connected. For example, the inspection terminal 38a may be simply in direct contact with the inspection land 38. Alternatively, the inspection terminal 38a may be fixed to the inspection land 38 by soldering. In addition, a coaxial connector may be used to connect between the inspection land 38 and the inspection terminal 38a.

A connection terminal of an external inspection device 100 is connected to the inspection terminal 38a and configured to allow various kinds of inspection information (such as data and signals) to be transmitted and received to and from the secondary unit 32 through the inspection terminal 38a and the inspection land 38. It should be noted that there is provided a path switching switch 39 (not illustrated in FIG. 3) between the inspection land 38 and a connection point in the electrical path extending from the secondary front-end circuit 33 to the secondary antenna 34 as illustrated in FIG. 2. The path switching switch 39, which is in an on state, enables the inspection land 38 to be connected to the electrical path extending from the secondary front-end circuit 33 to the secondary antenna 34.

As illustrated in FIG. 5, the battery control device 40 is mounted on a first portion of the inner wall of the housing 50, and the secondary board 36 including the secondary antenna 34 is arranged adjacent to a second portion of the inner wall of the housing 5, the second portion facing the first portion of the inner wall on which the battery control device 40 is mounted. The secondary antenna 34 is arranged so as to face the battery control device 40.

The circular holes 37A to 37D arranged close to the respective corners of the secondary board 36 are connected to the housing 50 that serves as a ground member, so that the circuits included in the secondary board 36 are grounded. Additionally, at the time of grounding, it is desirable to ground a back surface of the secondary board 36 opposite to the front surface thereof on which the secondary antenna 34 and the inspection land 38 are disposed.

The front surface of the secondary board 36 includes a high-voltage region 36a in which a high voltage (for example, several hundred volts) is present, and low-voltage regions 36b in each of which a lower voltage (for example, several tens of volts) is present as compared with the high-voltage region 36a. The secondary unit 32, the secondary front-end circuit 33, the secondary antenna 34, the equalization circuit 35, and the like are disposed in the high-voltage region 36a of the front surface of the secondary board 36. Meanwhile, the low-voltage regions 36b of the front surface of the secondary board 36 are arranged in regions around the respective circular holes 37A to 37D that are fixed to the housing 50. The low-voltage regions 36b, i.e., their conductor patterns, are grounded to the housing 50 through the circular holes 37A to 37D. All the circular holes 37A to 37D are grounded in the present embodiment, but any of the circular holes 37A to 37D alone may be grounded.

In addition, the front surface of the secondary board 36 includes a boundary region 36c arranged between the high-voltage region 36a and the low-voltage regions 36b. The boundary region 36c defines a partition between the high-voltage region 36a and the low-voltage regions 36b. It should be noted that the boundary region 36c is provided with electrical paths L31 for respectively grounding the electrical circuits provided in the high-voltage region 36a to the housing 50, which serves as the ground member, through the circular holes 37A to 37D disposed in the low-voltage regions 36b. Common capacitors 36d are for example mounted on the respective electrical paths L31 for removing, from high-voltage region 36a, common noise or another noise from the high-voltage region 36a and for discharging the removed noise to the housing serving as the ground member through the circular holes 37A to 37D.

In addition, the high-voltage region 36a of the secondary board 36 is defined by one or more electronic components and one or more electrical paths (conductor patterns) through which a high-voltage current flows. At least regions surrounding the electronic components and the electrical paths through which the high-voltage current flows are included in the high-voltage region 36a. Similarly, the low-voltage regions 36b of the secondary board 36 are defined by one or more electronic components and one or more electrical paths (conductor patterns) through which a low-voltage current flows as compared with the high-voltage current flowing in the high-voltage region 36a. At least regions surrounding the electronic components and the electrical paths through which the low-voltage current flows are included in the low-voltage regions 36b.

The boundary region 36c serves as an insulated region. The boundary region 36c is a region in which no electrical paths other than the electrical paths L31 connecting the high-voltage region 36a and the low-voltage regions 36b are disposed. In FIG. 3, the boundary 36c is hatched. As illustrated in FIG. 3, it is desirable that the boundary region 36c has certain widths that cause the high-voltage region 36a to be sufficiently spaced apart from the low-voltage regions 36b as illustrated in FIG. 3.

The inspection land 38 is mainly used for an inspection of a prototype of the secondary board 36 and is typically not used in the mass production stage of the secondary board 36, although it may be used. The inspection terminal 38a is therefore not attached to a mass-produced product of the secondary board 36, so that the conductor (copper foil portion) of the inspection land 38 is exposed.

In such a case, let us assume that
(I) A first case where the inspection land 38 disposed in the high-voltage region 36a of the secondary board 36 is located at a position close to one of the low-voltage regions 36b of the secondary board 36, or
(II) A second case where the inspection land 38 mounted in the high-voltage region 36a of the secondary board 36 is located at a position close to the inner wall of the housing 50 having the same potential as that of one of the low-voltage regions 36b.

Either the first case or the second case may increase the possibility of insulation breakdown between the inspection land 38 and the selected low-voltage region 36b (or the housing 50) depending on the potential difference therebetween.

That is, an electrical path provided in the high-voltage region 36a of the secondary board 36 may be short-circuited to an electrical path (or the housing 50) provided in the selected low-voltage region 36b through the inspection land 38.

From this viewpoint, the inspection land 38 according to the present embodiment is arranged further from at least one of the low-voltage regions 36b than the electronic component located closest to the at least one low-voltage region 36b (or the housing 50). For example, the inspection land 38 is arranged farther from the upper right circular hole 37A than the secondary front-end circuit 33 closest to the circular hole 37A. That is, any of the electronic components 61a to 61e included in the secondary front-end circuit 33 is disposed between the upper right circular hole 37A (and the low-voltage region 36b therearound) and the inspection land 38 in FIG. 3.

Similarly, the secondary front-end circuit 33 is arranged between the boundary region 36c and the inspection land 38, and the secondary unit 32 is disposed between the lower right circular hole 37B (and the low-voltage region 36b therearound) and the inspection land 38 in FIG. 3. Additionally, at least the equalization circuit 35 is disposed between the upper left or lower left circular hole 37C or 37D (and the low-voltage region 36b therearound) and the inspection land 38 in FIG. 3.

In addition, the secondary antenna 34 is sensitive to heat. One of the secondary antenna 34 and the equalization circuit 35 is therefore arranged closer to the outer edge portion of the secondary board 36 and the other is arranged closer to the central portion of the secondary board 36.

Specifically, the secondary antenna 34 is disposed near the left end of the secondary board 36 and the equalization circuit 35 is arranged generally in a central region of the front surface of the secondary board 36. Additionally, it is desirable that the secondary antenna 34 be sufficiently spaced apart from the monitoring IC power supply 81 and the wireless IC power supply 82 which may be sources of heat.

In addition, the secondary board 36 is fixed to the housing 50 through the circular holes 37A to 37D using screws and the like. This applies stress to the regions of the secondary board 36 near the circular holes 37A to 37D thereof because of, for example, the screws. Once stress is applied to the secondary board 36, the secondary board 36 may be distorted and the circuits and the wireless secondary antenna 34 mounted to the secondary board 36 may be accordingly changed in impedance. This may result in frequency characteristics of radio waves and currents related to the circuits and the wireless secondary antenna 34 may be influenced.

It is therefore desirable that the secondary antenna 34 and the inspection land 38 be each spaced apart from the circular holes 37A to 37D by a predetermined interval or more. Accordingly, the circular holes 37A to 37D are disposed closely adjacent to the respective corners of the secondary board 36. The secondary antenna 34 and the inspection land 38 are disposed inwardly of the corners of the secondary board 36.

In addition, the secondary board 36 is fixed to the housing 50 through the plurality of circular holes 37A to 37D using screws and the like. Therefore, stress is also applied easily to the straight-line region of the secondary board 36; the straight-line region connects between any pair of the circular holes 37A to 37D. This may result in the secondary board 36 being easily deformed.

From this viewpoint, the secondary antenna 34 and the inspection land 38 are preferably arranged so as to avoid the straight-line region connecting between any pair of the circular holes 37A to 37D. In the present embodiment, the inspection land 38 is disposed so as to avoid the straight-line region connecting between each pair of the circular holes 37A to 37D.

The secondary board 36 is housed in the housing 50. As illustrated in FIG. 5, the outer edge portion of the secondary board 36 is disposed opposite to, and close to, the inner wall of the housing 50. That is, there are few spaces between the outer edge portion of the secondary board 36 and the inner wall of the housing 50. Accordingly, the inspection land 38 is arranged closer to the inner side of the secondary board 36 than the secondary antenna 34, so as to be located farther from the inner wall of the housing 50 than the secondary antenna 34. As a result, even when the battery monitoring device 30 is housed in the housing 50, the inspection terminal 38a can be easily inserted into and removed from the inspection land 38 without being obstructed by the inner wall of the housing 50.

The radiation pattern (i.e., a radiation intensity pattern of radio waves radiated) of the secondary antenna 34 is often not uniform depending on direction. This naturally applies when a directional antenna is adopted as the secondary antenna 34, but even an omnidirectional antenna exhibits slightly different radiation patterns depending on the circuit arrangement or the like.

Furthermore, in the case of a narrow communication space such as the inside of the housing 50, interference or the like easily changes the radiation pattern. The inspection land 38 has a possibility of causing mutual influence between the radiation pattern and the inspection land 38 because the inspection land 38 is a conductor as described above. For example, the inspection land 38 may cause noise in radio waves (wireless communication). In addition, radio waves generated from the secondary antenna 34 of the secondary board 36 during inspection thereof may cause noise in the circuits of the battery monitoring device 30 through the inspection land 38

Accordingly, the inspection land 38 is arranged outside a predetermined range centered on the radiation direction in which radio waves radiated from the secondary antenna 34 have the greatest radiant intensity.

In FIG. 3, the radiation direction in which radio waves radiated from the secondary antenna 34 have the greatest radiant intensity is indicated by an arrow Y1 and the predetermined range is indicated by one-dot chain lines. Additionally, it is sufficient if the predetermined range is set within a range of 0 degrees to 180 degrees. It is desirable that the inspection land 38 is arranged outside the predetermined range of 30 to 90 degrees. In the present embodiment, a range of 90 degrees centered on the direction in which radio waves radiated from the secondary antenna 34 have the greatest radiant intensity is set as the predetermined range. Additionally, in a case where wireless communication is performed between the primary unit 42 and the secondary unit 32, the direction connecting the primary antenna 44 and the secondary antenna 34 is highly likely to be the direction in which the radio waves have the greatest radiant intensity in general.

In addition, the secondary antenna 34 and the inspection land 38 may be disposed to face a metal part constituting the housing 50 or the casing of the assembled battery 20. That is, the secondary antenna 34 and the inspection land 38 may be covered with the metal part provided to the housing 50 or the casing of the assembled battery 20 in a predetermined direction. This causes the metal part to serve as an electromagnetic shield and reduces the influence of external noise.

### Shape and Circuit Arrangement of Primary Board

Next, the following describes the shape and the circuit arrangement of the primary board 46.

As illustrated in FIG. 4, the primary board 46 has a horizontally long rectangular shape, and the primary board 46 has formed therethrough circular holes 47A to 47D, which are disposed close to the respective corners of the primary board 46. The circular holes 47A to 47D serve as fastening members for fastening of the primary board 46 to the housing 50.

As illustrated in FIG. 4, predetermined electronic components including the measurement circuit 45 are mounted generally in a right region of a front surface of the primary board 46. Predetermined electronic components including the battery control MCU 41, a battery control MCU power supply 83, and a wireless IC power supply 84 are mounted generally in a central region of the front surface of the primary board 46. Predetermined electronic components including the primary unit 42, the primary front-end circuit 43, and the primary antenna 44 are mounted generally in a left region of the front surface of the primary board 46

In addition, in FIG. 4, a connector 41a included in the battery monitoring device 30, which is connected to a component located outside the primary board 46, such as the vehicle ECU 14, is attached to the right end of the primary board 46. The battery control MCU 41 is connected to the vehicle ECU 14 through the connector 41a and configured to be capable of transmitting the battery condition (battery information) of each of the battery cells 22. In addition, the battery control MCU 41 is configured to be capable of receiving instructions from the vehicle ECU 14.

It should be noted that the primary board 46 is a printed board as with the secondary board 36 and the respective electronic components are connected to one another by the conductor pattern laid out on the primary board 46. In addition, although not illustrated, electronic components included in the battery control device 40 other than the electronic components described above are also mounted to the primary board 46. The electronic components mounted to the primary board 46 include, for example, various electronic circuits and various circuit components (such as one or more capacitors, one or more switching elements, and one or more resistors).

In addition, the battery control MCU power supply 83 and the wireless IC power supply 84 are each a power converter serving as an electronic component that converts power supplied from a battery (such as an unillustrated auxiliary battery) and supplies the converted power to the battery control MCU 41 and the primary unit 42.

As illustrated in FIG. 2, the primary front-end circuit 43 is disposed in the electrical path between the primary unit 42 and the primary antenna 44. An inspection land 48 is mounted to the primary board 46 and configured to be connectable to the electrical path extending from the primary front-end circuit 43 to the primary antenna 44. The inspection land 48 has a configuration similar to that of the inspection land 38 of the secondary board 36. A pin-shaped inspection terminal 48a is disposed in the inspection land 48 so as to be electrically connected to the inspection terminal 48a. It should be noted that the inspection terminal 48a may have any shape.

Additionally, it may be optionally changed how to connect the inspection land 48 and the inspection terminal 48a as long as the inspection land 48 and the inspection terminal 48a are electrically connected. For example, the inspection terminal 48a may be simply in direct contact with the inspection land 48. Alternatively, the inspection terminal 48a may be fixed to the inspection land 48 by soldering. In addition, a coaxial connector may be used to connect between the inspection terminal 48a and the inspection land 48.

The external inspection device 100 is configured to be capable of transmitting and receiving various kinds of inspection information to and from the primary unit 42 through the inspection terminal 48a, the inspection land 48, and the primary front-end circuit 43. It should be noted that there is provided a path switching switch 49 between the inspection land 48 and a connection point in the electrical path extending from the primary front-end circuit 43 to the primary antenna 44 as illustrated in FIG. 2. The path switching switch 49, which is in the on state, enables the inspection land 48 to be connected to the electrical path extending from the primary front-end circuit 43 to the primary antenna 44.

A connector 45a to which the assembled battery 20 is connected is disposed close to the lower right circular hole 47B of the circular holes 47A to 47D provided at the respective corners of the primary board 46. This connector 45a is connected to at least any one of the positive terminal and the negative terminal of the assembled battery 20 to allow the highest potential and the lowest potential of the assembled battery 20 to be obtained (i.e., the inter-terminal voltage across the assembled battery 20 to be obtained) or allow any of the highest potential of the assembled battery 20, the lowest potential of the assembled battery 20, and the inter-terminal voltage across the assembled battery 20 to be obtained.

Thus, the connector 45a is a connector for acquiring a voltage used to detect insulation breakdown (electric leakage). Accordingly, the front surface of the primary board 46 includes a high-voltage region 46a in which a high voltage (for example, several hundred volts) is present, and a low-voltage region 46b in which a lower voltage (for example, several tens of volts) is present. More specifically, the measurement circuit 45 connected to the battery assembly 20 via the connector 45a is arranged in the high-voltage region 46a of the primary board 46.

On the other hand, the battery control MCU 41, the primary unit 42, the primary front-end circuit 43, the primary antenna 44, and the like are arranged in the low-voltage region 46b of the primary board 46. The front surface of the primary board 46 additionally includes a boundary region 46c formed thereon and arranged between the high-voltage region 46a and the low-voltage region 46b to separate the high-voltage region 46a and the low-voltage region 46b from one another.

It should be noted that the boundary 46c is provided with an electrical path L41 (illustrated using a dashed line) for transmitting a measurement result from the measurement circuit 45. The measurement circuit 45 measures the voltage across the assembled battery 20 through the circular hole 47B and transmits the voltage to the battery control MCU 41 and one or more other components mounted in the high-voltage region 46a.

In addition, the high-voltage region 46a of the primary board 46 is defined by one or more electronic components and one or more electrical paths (conductor patterns) through which a high-voltage current flows. At least regions surrounding the electronic components and the electrical paths through which the high-voltage current flows are included in the high-voltage region 46a. Similarly, the low-voltage region 46b of the primary board 46 is defined by one or more electronic components and one or more electrical paths (conductor patterns) through which a low-voltage current flows as compared with the high-voltage current flowing through the high-voltage region 46a. At least regions surrounding the electronic components and the electrical paths through which the low-voltage current flows are included in the low-voltage region 46b.

The boundary region 46c of the primary board 46 serves as an insulated region. The boundary 46c is a region in which no electrical paths other than the electrical path L41 connecting the high-voltage region 46a and the low-voltage region 46b are disposed. In FIG. 4, the boundary region 46c is illustrated with hatching. As illustrated in FIG. 4, it is desirable that the boundary region 46c has certain widths that cause the high-voltage region 46a to be sufficiently spaced apart from the low-voltage region 46b.

As with the inspection land 38, the inspection land 48 is mainly used for an inspection of a prototype of the primary board 46 and is typically not used in the mass production stage of the primary board 46, although it may be used. The inspection terminal 48a is therefore not attached to a mass-produced product of the primary board 46, so that the conductor (copper foil portion) of the inspection land 48 is exposed. This raises a problem similar to that of the inspection land 38 of the secondary board 36.

That is, the high-voltage region 46a and the low-voltage region 46b of the primary board 46 may be short-circuited through the inspection land 48 (or the inspection terminal 48a and the same applies below).

From this viewpoint, the inspection land 48 according to the present embodiment is arranged farther from the high-voltage region 46a than the electronic component located closest to the high-voltage region 46a. For example, the inspection land 48 is arranged farther from the high-voltage region 46a than the primary front-end circuit 43. That is, at least the primary front-end circuit 43 is disposed between the high-voltage region 46a and the inspection land 48 in FIG. 4.

In addition, the primary board 46 is fixed to the housing 50 through the circular holes 47A to 47D using screws and the like. This applies stress to the regions of the primary board 46 near the circular holes 47A to 47D thereof because of, for example, the screws. Once stress is applied to the primary board 46, the primary board 46 may be distorted and the circuits and the wireless primary antenna 44 mounted to the primary board 46 may be accordingly changed in impedance. The may result in frequency characteristics of radio waves and currents related to the circuits and the wireless primary antenna 44 may be influenced.

It is therefore desirable that the primary antenna 44 and the inspection land 48 be each spaced apart from the circular holes 47A to 47D by a predetermined interval or more. Accordingly, the circular holes 47A to 47D are disposed closely adjacent to the respective corners of the primary board 46. The primary antenna 44 and the inspection land 48 are disposed inwardly of the corners of the primary board 46.

In addition, the primary board 46 is fixed to the housing 50 through the circular holes 47A to 47D using screws and the like. Therefore, stress is also applied easily to the straight-line region of the primary board 46; the straight-line region connects between any pair of the circular holes 47A to 47D. This may result in the primary board 46 being easily deformed.

From this viewpoint, the primary antenna 44 and the inspection land 48 are preferably arranged so as to avoid the straight-line region connecting between any pair of the circular holes 47A to 47D. In the present embodiment, the inspection land 48 is disposed to avoid the straight-line region connecting between each pair of the circular holes 47A to 47D.

The primary board 46 is housed in the housing 50. As illustrated in FIG. 5, the outer edge portion of the primary board 46 is disposed opposite to, and close to, the inner wall of the housing 50. That is, there are few spaces between the outer edge portion of the primary board 46 and the inner wall of the housing 50. The inspection land 48 is therefore arranged closer to the inner side of the primary board 46 than the primary antenna 44, so as to be located farther from the inner wall of the housing 50 than the primary antenna 44. As a result, even when the battery control device 40 is housed in the housing 50, the inspection terminal 48a can be easily inserted into and removed from the inspection land 48 without being obstructed by the inner wall of the housing 50.

As with the secondary board 36, the inspection land 48 of the primary board 46 is arranged outside a predetermined range centered on the radiation direction in which radio waves radiated from the primary antenna 44 have the greatest radiant intensity.

In FIG. 4, the radiation direction in which radio waves radiated from the primary antenna 44 have the greatest radiant intensity is indicated by an arrow Y2 and the predetermined range is indicated by one-dot chain lines. Additionally, it is sufficient if the predetermined range is set within a range of 0 degrees to 180 degrees. It is desirable that the inspection land 48 is arranged outside the predetermined range of 30 to 90 degrees. In the present embodiment, a range of 90 degrees centered on the direction in which radio waves radiated from the primary antenna 44 have the greatest radiant intensity is set as the predetermined range.

In addition, as with the secondary board 36, the primary antenna 44 and the inspection land 48 may be disposed to face a metal part constituting the housing 50 or the casing of the assembled battery 20. This causes the metal part to function as an electromagnetic shield and reduces the influence of external noise.

The predetermined embodiment achieves the following advantageous benefits.

The secondary board 36 is provided with the inspection land 38 to which the inspection terminal 38a is to be connected. The external inspection device 100 is then configured to allow various kinds of inspection information to be transmitted to and received from the secondary unit 32 through the inspection terminal 38a and the inspection land 38.

This makes it possible to input and output various signals to and from a portion of the electrical path via the inspection land 38. It is therefore possible to separate inspection targets. For example, it is possible to inspect the characteristics of the secondary antenna 34 alone. This makes it possible to efficiently conduct inspections of the secondary board 36. It should be noted that the primary board 46 is also provided with the inspection land 48 similarly and it is possible to obtain such advantageous effects similar to those of the secondary board 36.

The inspection land 38 is disposed in a first region of the secondary board 36 and arranged farther from a second region of the secondary board 36 different from the first region than the electronic component located closest to the second region. Similarly, the inspection land 48 is disposed in a first region of the primary board 46 and arranged farther from a second region of the primary board 46 different from the first region than the electronic component located closest to the second region.

That is, an electronic component is disposed between the inspection land 38 or 48 and the second region different from the first region of the board 36 or 46 in which the inspection land 38 or 48 is disposed.

For example, in the high-voltage region 36a in which the inspection land 38 is disposed, any of the electronic components 61a to 61e included in the secondary front-end circuit 33 is disposed between the inspection land 38 and the low-voltage region 36b. In addition, the inspection land 38 is disposed farther from the circular hole 37A grounded to the housing 50 than any of the electronic components 61a to 61e located closest to the circular hole 37A. In addition, in the low-voltage region 46b in which the inspection land 48 is disposed, the electronic components 61a to 61e and the like included in the primary front-end circuit 43 are disposed between the inspection land 48 and the high-voltage region 46a. This makes it possible to restrain insulation breakdown from being caused between the high-voltage region 36a or 46a and the low-voltage region 36b or 46b through the inspection land 38 or 48.

One of the inspection land 38 and the equalization circuit 35 is disposed closer to the outer edge portion of the secondary board 36 and the other is disposed closer to the center of the secondary board 36. Similarly, one of the secondary antenna 34 and the equalization circuit 35 is disposed closer to the outer edge portion of the secondary board 36 and the other is disposed closer to the center of the secondary board 36. In the present embodiment, the inspection land 38 and the secondary antenna 34 are provided closer to the outer edge portion of the secondary board 36 and the equalization circuit 35 is provided closer to the center of the secondary board 36. This makes it possible to restrain heat generated from the equalization circuit 35 from influencing the secondary antenna 34, thus preventing the heat from causing communication failure.

The inspection land 38 is disposed between the monitoring IC 31 and a high-frequency circuit including the secondary unit 32, the secondary front-end circuit 33, and the secondary antenna 34. This makes it possible to discharge noise generated from the monitoring IC 31 to the inspection land 38. It is therefore possible to prevent the noise from being transmitted to the high-frequency circuit and prevent the radio wave characteristics of the high-frequency circuit from being adversely influenced. Similarly, it is possible to restrain high-frequency noise generated from the high-frequency circuit from influencing the monitoring IC 31, thus increasing the monitoring accuracy of the monitoring IC 31.

The circular holes 37A to 37D or 47A to 47D for fixation of the secondary board 36 or the primary board 46 to the housing 50 are provided at the outer edge portion of the secondary board 36 or the primary board 46. The inspection land 38 or 48 is disposed closer to the inner side of the secondary board 36 or the primary board 46 than the circular holes 37A to 37D or 47A to 47D. This makes it possible to favorably space the inspection lands 38 and 48 and the circular holes 37A to 37D and 47A to 47D apart from each other. It is thus possible to restrain distortion caused by stress from influencing the inspection land 38 or 48 in the regions close to the circular holes 37A to 37D or 47A to 47D when the secondary board 36 or the primary board 46 is fixed using screws and the like. This makes it possible to restrain the impedance from changing and accurately conduct an inspection.

In addition, the inspection land 38 or 48 and the wireless antenna 34 or 44 are disposed to avoid the regions on the straight lines connecting the circular holes 37A to 37D or 47A to 47D to each other. This makes it possible to restrain distortion caused by stress from influencing the inspection land 38 or 48 and the wireless antenna 34 or 44 on the straight lines connecting the circular holes 37A to 37D or 47A to 47D to each other. This makes it possible to restrain the impedance from changing and accurately conduct an inspection. In addition, it is possible to reduce the influence on the wireless antenna 34 or 44.

The secondary board 36 is housed in the housing 50. As illustrated in FIG. 5, the outer edge portion of the secondary board 36 is disposed to be opposite to the inner wall of the housing 50. The inspection land 38 is therefore disposed closer to the inner side of the secondary board 36 than the secondary antenna 34 to be located farther from the inner wall of the housing 50 than the secondary antenna 34. This makes it easy to pull the inspection terminal 38a out of the inspection land 38 and insert the inspection terminal 38a to the inspection land 38 without being obstructed by the inner wall of the housing 50.

Similarly, the outer edge portion of the primary board 46 is located opposite to the inner wall of the housing 50. The inspection land 48 is therefore disposed closer to the inner side of the primary board 46 than the primary antenna 44 to be located farther from the inner wall of the housing 50 than the primary antenna 44. This makes it easy to pull the inspection terminal 48a out of the inspection land 48 and insert the inspection terminal 48a to the inspection land 48.

The secondary front-end circuit 33 or the primary front-end circuit 43 is arranged between the boundary region 36c or 46c of the board 36 or 46 and the inspection land 38 or 48. This makes it possible to favorably restrain insulation breakdown from being caused in the board 36 or 46.

The inspection land 38 or 48 is arranged outside a range of 90 degrees centered on the radiation direction (Y1 or Y2) in which radio waves radiated from the wireless antenna 34 or 44 have the greatest radiant intensity. This makes it possible to reduce noise generated in radio waves due to the existence of the inspection land 38 or 48. In addition, it is possible to reduce noise based on radio waves from the secondary antenna 34 through the inspection land 38 during inspection of the secondary board 36.

The equalization circuit 35 is disposed closer to the inspection land 38 than the secondary antenna 34. This dissipates heat generated by the equalization circuit 35 through the inspection land 38, making it possible to restrain the heat from being transmitted to the secondary antenna 34. It is therefore possible to restrain the influence of the heat from causing a trouble in wireless communication using the secondary antenna 34.

The wireless antenna 34 or 44 and the inspection land 38 or 48 may be arranged to be opposite to a metal part constituting the housing 50 or the casing of the assembled battery 20. In this arrangement, the metal part of the housing 50 or the casing functions as an electromagnetic shield, making it possible to reduce external noise.

The circular hole 37A closest to the secondary antenna 34 among the plurality of circular holes 37A to 37D is disposed closer to one of the sides of the secondary board 36 than a different side of the secondary board 36 which the secondary antenna 34 is disposed adjacent to. That is, the secondary antenna 34 is disposed adjacent to a long side of the secondary board 36 and the circular hole 37A closest to the secondary antenna 34 is disposed adjacent to a short side of the secondary board 36. This makes it possible to restrain distortion of a portion of the secondary board 36 that is located around the circular hole 37A from influencing the secondary antenna 34.

The connector 41a for a wired connection to the vehicle ECU 14 that is an external device is provided at one of the right and left ends of the primary board 46 and the primary antenna 44 is disposed at the other of the right and left ends. This makes it possible to prevent radio waves from the primary antenna 44 from interfering with the connector 41a and being blocked. That is, it is possible to restrain the connector 41a from obstructing wireless communication.

As illustrated in FIG. 5, while the secondary antenna 34 is disposed on the right side of the secondary board 36, the primary antenna 44 is disposed on the left side of the primary board 46. That is, the secondary board 36 is disposed at one of both ends of the primary board 46 at which the primary antenna 44 is provided. This makes it possible to decrease the distance between the primary antenna 44 and the secondary antenna 34 and decrease obstacles. It is thus possible to favorably perform wireless communication.

### MODIFICATIONS

The configurations according to the present embodiment set forth above may be modified as follows. The following describes the modifications.

In the embodiment, the equalization circuit 35 may be disposed at the outer edge portion of the secondary board 36 and the inspection land 38 may be arranged generally in a central region of the first surface of the secondary board 36.

In the embodiment, the inspection land 38 is disposed closer to the middle of the secondary board 36 than one of the circular holes 37A to 37D closest to the inspection land 38. However, the inspection land 38 may be disposed adjacent to one side of the secondary board 36, and one of the circular holes 37A to 37D located closest to the inspection land 38 may be disposed adjacent to the opposite side of the secondary board 36.

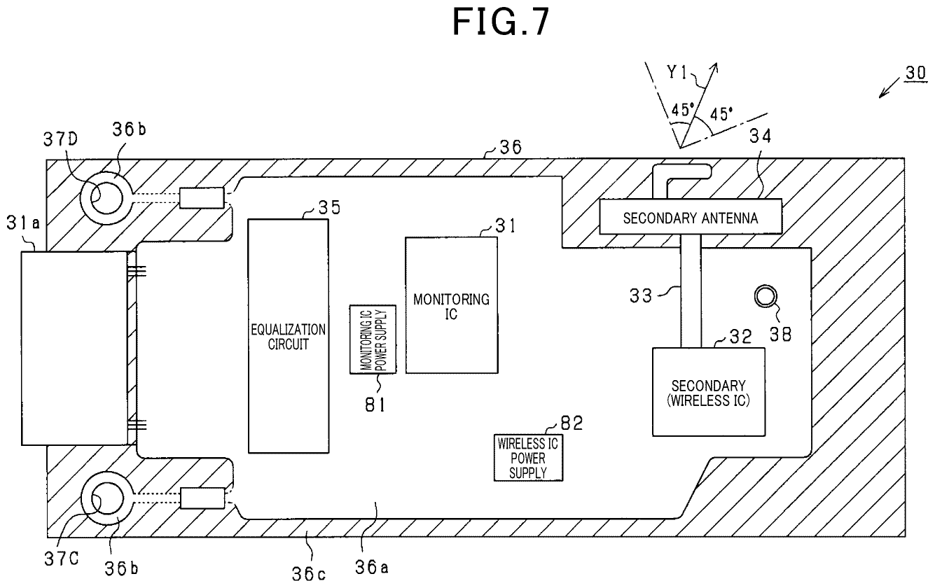

For example, in a case where the circular holes 37C and 37D are arranged adjacent to only the left side of the secondary board 36 as illustrated in FIG. 7, it is favorable to dispose the inspection land 38 closer to the right side of the secondary board 36 than to the left side thereof. This makes it possible to restrain distortion of a portion of the secondary board 36 located closer to the circular hole 37C or 37D from influencing the inspection land 38.

Similarly, the inspection land 48 may be arranged adjacent to the side of the secondary board 36 that is opposite to the side which the circular hole 47D located closest to the inspection land 48 is located adjacent to. For example, in a case where a circular hole is arranged adjacent to only the right side of the primary board 46, the inspection land 48 may be arranged adjacent to the left side of the secondary board 36.

In the embodiment, the equalization circuit 35 is disposed closer to the inspection land 38 than the secondary antenna 34, that is, disposed adjacent to the inspection land 38, but may be disposed adjacent to the secondary antenna 34.

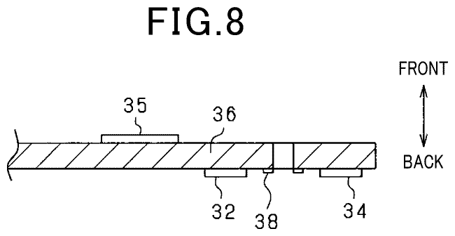

In the embodiment, the secondary board 36 may be configured to allow respective elements and circuits to be disposed on the front surface and the back surface thereof. In this medication, as illustrated in FIG. 8, the surface on which the equalization circuit 35 is disposed may be different from the surface on which the inspection land 38 is disposed. In addition, the surface on which the equalization circuit 35 is disposed may be different from the surface on which the secondary unit 32 is disposed. Similarly, the surface on which the equalization circuit 35 is disposed may be different from the surface on which the secondary antenna 34 is disposed. This makes it possible to restrain heat generated by the equalization circuit 35 from being transmitted to the secondary unit 32 and the inspection land 38 during inspection of the secondary board 36. It is therefore possible to accurately conduct inspection of the secondary board 36. In addition, in this modification, it is desirable to connect the ground member (such as the housing 50) on the surface opposite to the surface on which the secondary antenna 34 and the inspection land 38 are disposed. This makes it possible to restrain noise from being transmitted to the secondary antenna 34 and the inspection land 38 from the ground member.

Similarly, the monitoring IC power supply 81 that may be a source of heat may be mounted on the surface of the secondary board 36 opposite to the surface of the secondary board 36 on which the wireless devices (the secondary wireless IC 32, the secondary front-end circuit 33, and the secondary wireless antenna 34) are mounted. The battery control MCU power supply 83 may also be mounted on the surface of the secondary board 36 opposite to the surface of the secondary board 36 on which the wireless devices are mounted.

In the embodiment, the wireless IC power supply 82 or 84 may preferably disposed apart from each of the wireless devices (the secondary wireless IC 32, the secondary front-end circuit 33, and the secondary wireless antenna 34 or the primary wireless IC 42, the primary front-end circuit 43, and the primary wireless antenna 44) by a predetermined distance. The predetermined distance is, for example, a distance greater than or equal to the size of the power supply circuit of the wireless IC power supply 82 or 84.

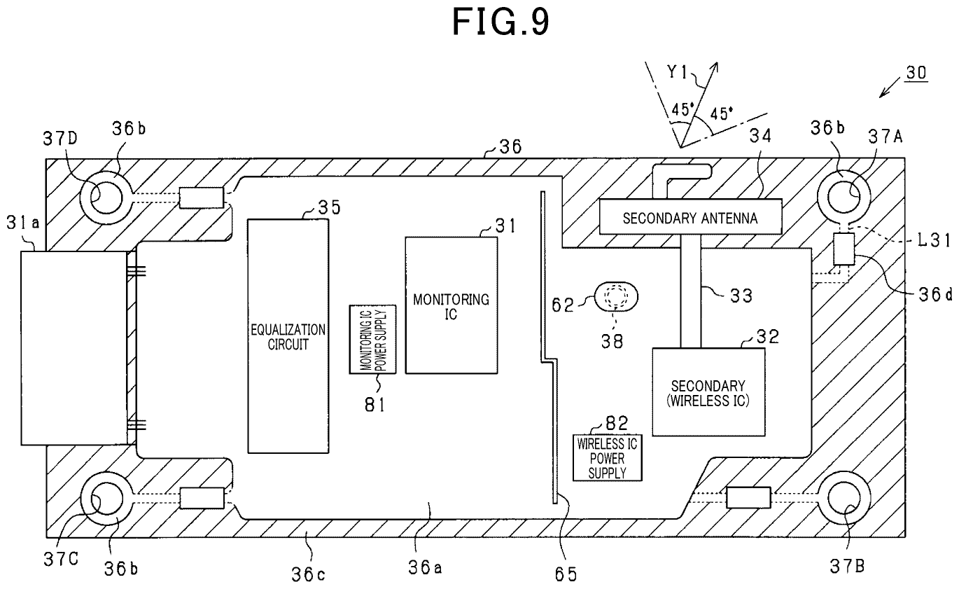

In the embodiment, the inspection lands 38 and 48 may be each sealed by a sealing member 62 including an insulating material such as resin as illustrated in FIG. 9 after inspection of the secondary or primary board 36 or 46. This makes it possible to restrain insulation breakdown from being caused through the inspection lands 38 and 48.

In the embodiment, the inspection land 38 may be disposed apart from the secondary front-end circuit 33 by a predetermined distance or more.

In the embodiment, the path switching switch 39 is configured to enable the electrical path connected to the inspection land 38 and the electrical path connected to the secondary antenna 34 to be connected to one another as illustrated in FIG. 2. However, the configuration related to the connection may be optionally changed.

For example, the electrical path connected to the inspection land 38 and the electrical path connected to the secondary antenna 34 may be connected using a short-circuit element. In addition, a configuration may be adopted in which the electrical path connected to the inspection land 38 and the electrical path connected to the secondary antenna 34 may be both connected to an electrical path to which the secondary unit 32 is connected. Then, an electronic component (such as a band-pass filter) may be disposed in at least one of the electrical path connected to the inspection land 38 and the electrical path connected to the secondary antenna 34, and the electronic component may be configured to select whether to transmit a signal to the transmit secondary antenna 34.

Similarly, in the battery control device 40, a connection component between the electrical path connected to the inspection land 48 and the electrical path connected to the primary antenna 44 may be optionally changed.

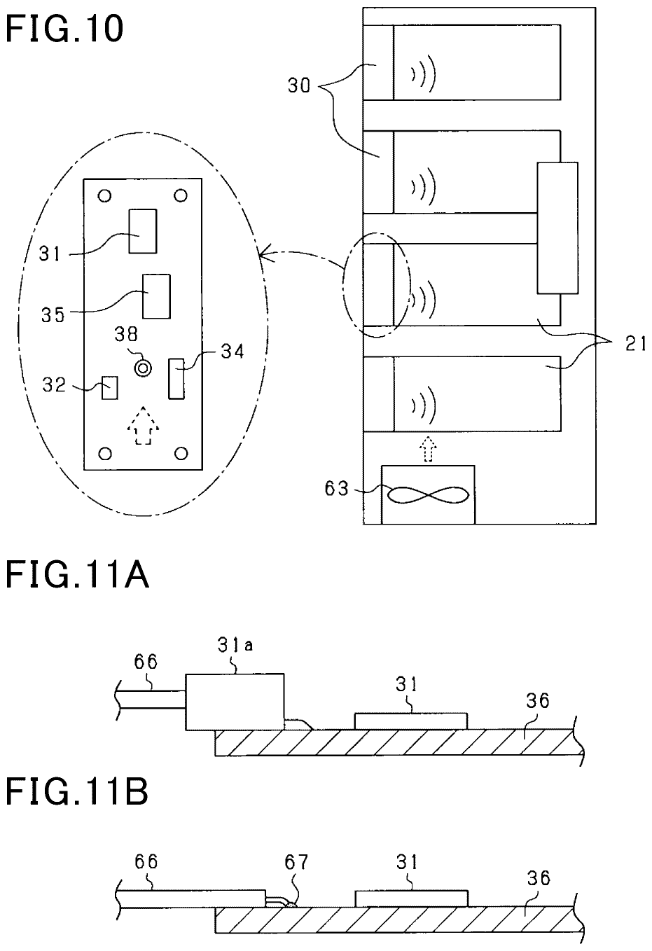

The battery pack 11 according to the embodiment may be provided with a cooling blower 63 that generates wind to cool the assembled battery 20. In this modification, as illustrated in FIG. 10, the equalization circuit 35 may be disposed on the downstream of the secondary antenna 34 and the inspection land 38 in the path of wind generated by the cooling blower 63. FIG. 10 schematically illustrates, using an arrow, the wind direction and the path of wind. That is, the secondary antenna 34 and the inspection land 38 may be disposed on the upstream of the equalization circuit 35 in the path of window, and the equalization circuit 35 may be disposed on the downstream of the secondary antenna 34 and the inspection land 38 in the path of window. This makes it possible to restrain, even if the equalization circuit 35 generates heat, the heat from being transmitted to the secondary antenna 34 and the inspection land 38 through air currents (air).

In the embodiment, the inspection land 38 is disposed between the monitoring IC 31 and the high-frequency circuit including the secondary unit 32, the secondary antenna 34, and the secondary front-end circuit 33, but the inspection land 38 may not be disposed between them.

In the embodiment, a slit or a groove 65 may be formed in the front surface of the secondary board 36 and arranged between (i) the high-frequency circuit including the secondary unit 32, the secondary antenna 34, the secondary front-end circuit 33, and the like, and (ii) both the monitoring IC 31 and the equalization circuit 35 as illustrated in FIG. 9. This makes it possible to restrain high-frequency noise generated from the high-frequency circuit from influencing the monitoring IC 31 and the like, thus increasing the monitoring accuracy.

In the embodiment, the secondary board 36 of the battery monitoring device 30 is connected to the battery cells 22 through the connector 31a as illustrated in FIG. 11A. If described in more detail, detection lines 66 connected to the corresponding battery cells 22 are connected to the secondary board 36 through the connector 31a. As a modification of the above configuration, the detection lines 66 connected to the corresponding battery cells 22 may be connected to the secondary board 36 of the battery monitoring device 30 by soldering as illustrated in FIG. 11B. The solder connections 67 formed on the secondary board 36 are easy to decrease in height with respect to the connector 31a. This therefore makes it possible to reduce interference of the connections with radio waves transmitted and received to and from the secondary antenna 34.

In the embodiment, the primary antenna 44 may be a directional antenna having the high radiant intensity of radio waves in a predetermined radiation direction. In this modification, it is desirable to provide the connector 41a in the direction opposite to the radiation direction Y2 (the direction in which radio waves have the highest radiant intensity) of the directional antenna as in FIG. 4. This makes it possible to restrain the connector 41a from blocking radio waves from the primary antenna 44.

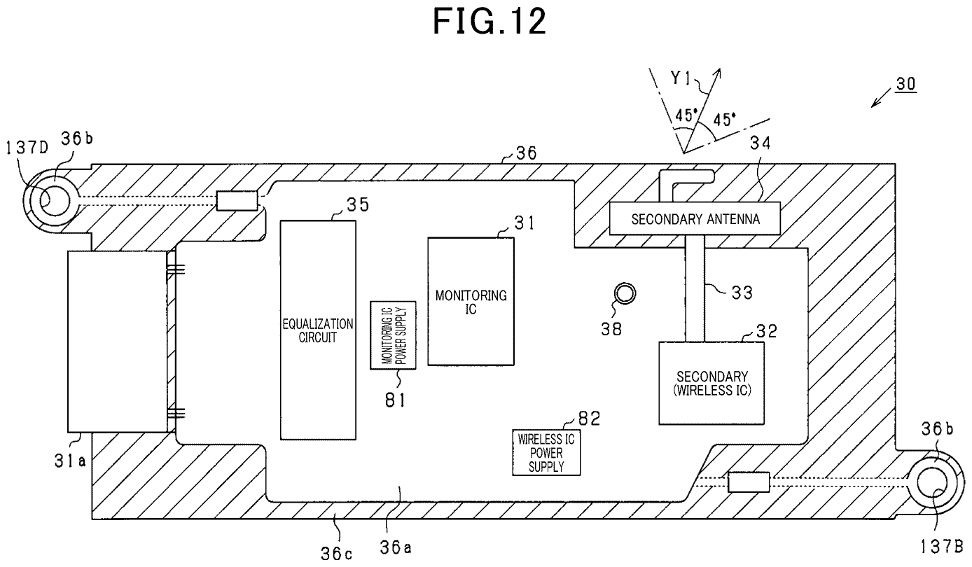

At least one circular hole, which serves as a fastening member for fastening of the secondary board 36 to the housing 50, may be formed through a corresponding at least one protrusion protruding from at least one side of the secondary board 36. FIG. 12 illustrates circular holes 137B and 137D are formed through respective protrusions protruding from short sides of the secondary board 36. In this modification, the secondary antenna 34 may be mounted on an outer edge portion of the secondary board 36 so as to be disposed adjacent to one of the remaining sides of the secondary board 36 (for example, long sides in FIG. 12); no protrusions are protruded from the respective remaining sides of the secondary board 36. This makes it possible to restrain the fastening members disposed in the circular holes to protrude therefrom from blocking radio waves from the secondary antenna 34. If described in more detail, this configuration makes it possible to prevent, for example, screws disposed in the respective circular holes 137B and 137D from obstructing the radio waves.

In the embodiment, the secondary board 36 and the primary board 46 are connected to the busbar 16 (power supply path) to which the assembled battery 20 and an electrical load such as the motor 13 are connected. If described in more detail, the secondary board 36 is directly or indirectly connected to the busbar 16 so as to be connected to the battery cells 22 through the connector 31a. In addition, the primary board 46 is directly or indirectly connected to the busbar 16 so as to be connected to the assembled battery 20 through the circular hole 47B.

Noise generated from the power converters such as the PCU 12 and the relay switch 15 including one or more switching elements may flow through the busbar 16 as illustrated in FIG. 1. This noise may thus flow into, for example, the front-end circuit 33 or 43 of the board 36 or 46 through the busbar 16, causing communication issues.

From this viewpoint, the power converters such as the PCU 12 and the relay switch 15 may be connected to a ground member, such as a chassis ground, so that noise generated by on/off control of the switching elements of the power converters is discharged to the ground member. This enables the strength of noise (the magnitude of current or voltage) flowing from the busbar 16 to the front-end circuit 33 or 43 to become less than or equal to the current flowing through the front-end circuit 33 or 43 or the voltage across the front-end circuit 33 or 43. This makes it possible to reduce the influence of the noise, thus suitably performing communication. In addition, the secondary unit 32, the secondary antenna 34, and the like can be disposed adjacent to the side of the secondary board 36 to which the connector 31a is mounted, that is, can be disposed adjacent to the connector 31a.

In the embodiment, the connecting conductors are not limited to the inspection lands 38 and 48 and may be pads.

In the embodiment, the high-frequency circuits such as the wireless ICs 32 and 42 and the front-end circuits 33 and 43 may be each covered with a shield can (a metal shield casing). This makes it possible to reduce the influence of noise.

In the embodiment, the circuit boards 36 and 46 are not each limited to a quadrangular shape and may be changed to have any shape. Boards each having a polygonal shape or a circular shape may be adopted.

As another example of the embodiment, inspection performed by the inspection apparatus 100 is carried out, prior to mass production of circuit boards 36 and 46 (i.e., the secondary board 36 and primary board 46, hereinafter collectively referred to as “circuit boards 36 and 46”), using representative circuit boards 36 and 46 (that is, prototype circuit boards).

When it is confirmed, based on the representative circuit boards 36 and 46, that desired performance is ensured, mass production of the circuit boards 36 and 46 is performed. Because the circuit boards 36 and 46 for mass production have been confirmed to have the desired performance by inspection performed prior to mass production, inspection is normally not performed on the mass-produced circuit boards. Accordingly, the inspection land 38 and the inspection terminal 38a are, in principle, unnecessary for the mass-produced circuit boards 36, and the inspection land 48 and the inspection terminal 48a are, in principle, unnecessary for the mass-produced circuit boards 46. However, if these are removed, there is a possibility that electrical characteristics may differ from those of the representative circuit boards 36 and 46 (prototypes) that were inspected prior to mass production. Therefore, in order to prevent changes in electrical characteristics, at least the inspection lands 38 and 48 are provided on the respective mass-produced circuit boards 36 and 46.

In the embodiment, an inspection by the inspection device 100 may be conducted in the mass production stage. The inspection in the mass production stage may be then conducted for all the circuit boards 36 and 46. Alternatively, the representative circuit boards 36 and 46 alone may be inspected using a sampling inspection or the like. Additionally, as long as all the circuit boards 36 and 46 for mass production are provided with the inspection lands 38 and 48, the inspection terminals 38a and 48a may be provided or do not have to be provided.

In the embodiment, the circular holes 37A to 37D or 47A to 47D serving as fastening members may be optionally changed in shape, number, and arrangement.

In the embodiment, the arrangement of each of the battery blocks 21, the battery monitoring devices 30, and the battery control device 40 may be optionally changed. For example, as illustrated in FIG. 13A, each of the battery monitoring devices 30 may be disposed at one end of the corresponding one of the battery blocks 21 in the long-side direction. Specifically, in FIG. 13A, the battery monitoring devices 30 may be disposed adjacent to both ends of the housing 50 in the short-side direction (both ends in the left-right direction).

The battery control device 40 may be mounted on one side of the battery block 21 so as to be located adjacent to one end of the housing 50 in the long-side direction. In this modification, the battery control device 40 may be disposed on the upper end of the side of the battery block 21 in the up-down direction as illustrated in FIG. 13B. This arrangement enables wireless communication between the battery monitoring devices 30 and the battery control device 40 to be performed through the upper space (the space above the battery blocks 21) of the housing 50.

In addition, mounting the battery monitoring devices 30 or the battery control device 40 on one side of at least one battery block 21 enables the height of the battery pack 11 to be lower in comparison with a case where the battery control device 40 is mounted on the top side of at least one battery block 21.

In the embodiment, the secondary antenna 34 and the primary antenna 44 may be preferably disposed closer to the battery monitoring device 30 or the battery control device 40, which serves as a communication partner, than the inspection lands 38 and 48.

In the embodiment, the secondary antenna 34 and the primary antenna 44 may be preferably disposed above the respective inspection lands 38 and 48 so as to be close to the top of the housing 50. This makes it possible to allow the secondary antenna 34 and the primary antenna 44 to perform wireless communication by favorably using the upper space of the housing 50 without being influenced by the inspection lands 38 and 48 (or without influencing the inspection lands 38 and 48).

In the embodiment, in a case where a directional antenna is used, it is desirable to adjust the directivity of radio waves from the directional antenna such that the upper space of the housing 50 is used. In that case, the directional antenna may be preferably arranged such that the direction of the directional antenna, i.e., the directivity of radio waves transmitted from the directional antenna, faces the receiver side. In addition, in that case, the inspection lands 38 and 48 may be preferably arranged in a direction opposite to the direction of the directional antenna, i.e., the directivity of radio waves transmitted from the directional antenna.

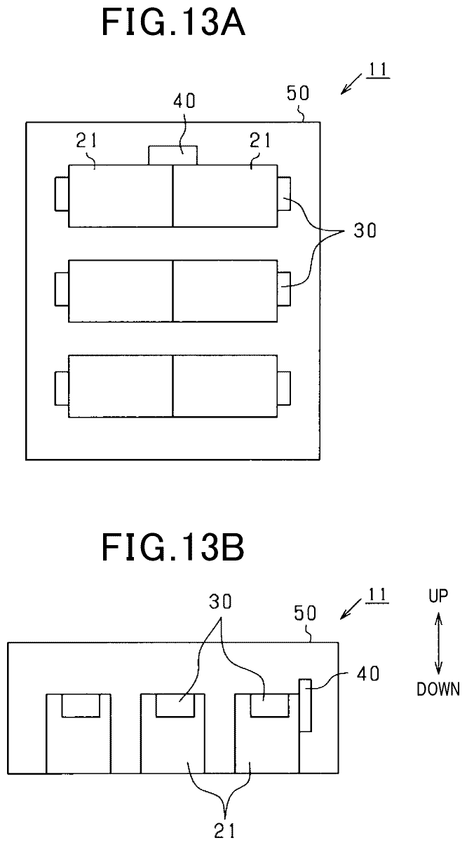

A modified housing 150 corresponding to the housing 50 may be formed of resin, and a lid member 152 of the housing 150 may be fixed to a body of the housing 150 by thermal stacking 151 as illustrated in FIG. 14 without using any metal components such as bolts. The housing 150, which is constructed by no metal parts, makes it possible to prevent wireless radio waves from being irregularly reflected thereby, thus preventing the antenna characteristics from unnecessarily deteriorating. It should be noted that circular holes 237A and 237C serving as members for both fastening of the secondary board 36 to the housing 150 and connection of the secondary board 36 to the ground member may be formed through protrusions protruding outwardly from the housing 150.

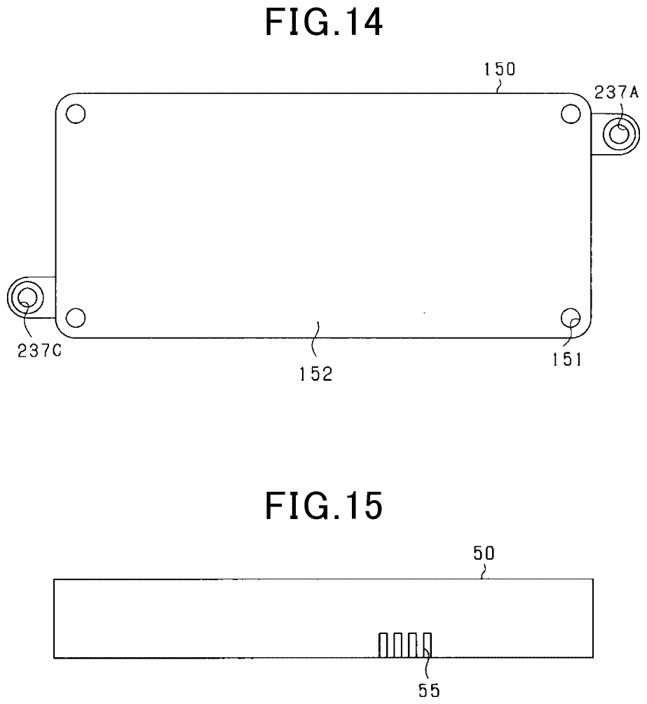

In the embodiment, the housing 50 may be provided with heat dissipation slits 55 as illustrated in FIG. 15. The heat dissipation slits 55 are formed at any positions of the housing 50. In particular, the heat dissipation slits 55 may be formed at or around positions of the housing 50. The positions of the housing 50 are located to face one or more components, such as the equalization circuit 35, the monitoring IC 31, and the battery control MCU 41, which require heat dissipation. Additionally, the heat dissipation slits 55 may be formed at or around positions of the housing 50. The positions of the housing 50 are located to face members, such as the antennas 34 and 44 and the inspection lands 38 and 48, which are sensitive to noise. In addition, the heat dissipation slits 55 may be preferably formed at the lower portion or bottom of the housing 50, which aim to prevent foreign objects from entering the housing 50 therethrough.

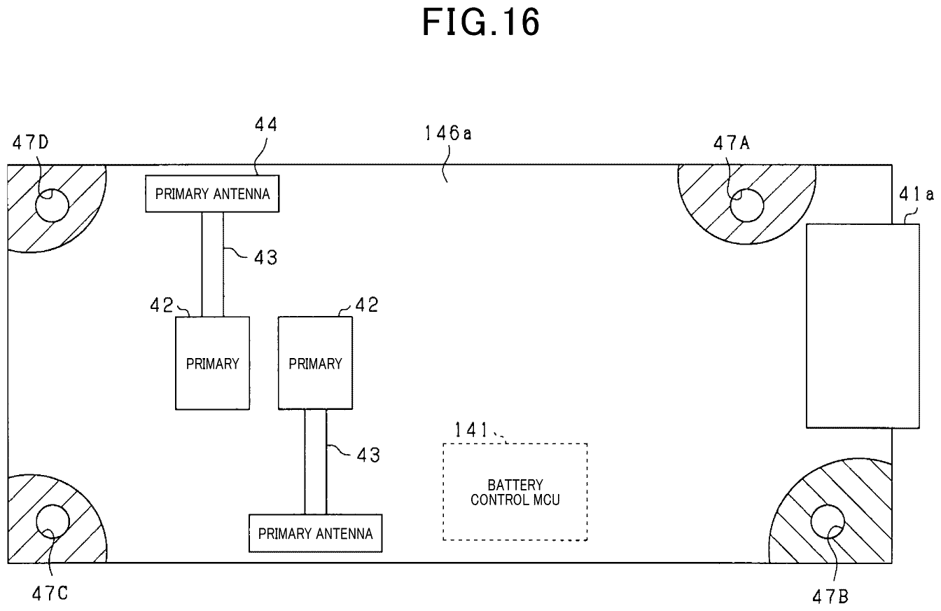

In the embodiment, the primary board 46 may include a plurality of wireless devices (primary wireless ICs 42, primary front-end circuits 43, and primary wireless antennas 44). In this modification, as illustrated in FIG. 16, two primary wireless ICs 42 may be arranged generally in a middle region of the front surface of the secondary board 36 in the short-side direction thereof, one of two primary wireless antennas 44 may be arranged at one end (i.e., the upper end in FIG. 16) of the front surface of the secondary board 36 in the short-side direction thereof, and the other of the two primary wireless antennas 44 may be arranged at the other end (i.e., the lower end in FIG. 16) of the front surface of the secondary board 36 in the short-side direction thereof. In this modification, the wireless devices may be arranged in a narrow space of a surface of the secondary board 36, making it possible to improve the area efficiency of a surface of the secondary board 36 on which the wireless devices are mounted. This modification additionally makes it possible to reduce mutual influence of wireless radio waves among the wireless devices.

In addition, as illustrated in FIG. 16, a battery control MCU 141 indicated by a dashed line may be disposed on the other surface, i.e., the back surface, of the secondary board 36, which is opposite to the surface (front surface) on which the wireless devices are mounted.

That is, the wireless devices have to be arranged in consideration of the propagation of radio waves and have a restriction on their arrangement positions on the circuit board. It is therefore difficult to handle wiring lines between the primary wireless IC 42 and the battery control MCU 141 in some cases.

From this viewpoint, the battery control MCU 141 may be mounted on the back surface and the back surface on which fewer electronic components are mounted may be used as a wiring portion to allow for easy wiring between the primary wireless IC 42 and the battery control MCU 141.

The control units and the techniques thereof described in the present disclosure may be implemented by a dedicated computer provided by configuring a processor and a memory programed to execute one or more functions specified as a computer program. Alternatively, the control units and the techniques thereof described in the present disclosure may be implemented by a dedicated computer provided by configuring a processor using one or more dedicated hardware logic circuits. Alternatively, the control units and the techniques thereof described in the present disclosure may be implemented by one or more dedicated computers each including a combination of a processor and a memory programmed to execute one or more functions and a processor including one or more hardware logic circuits. In addition, the computer program may be stored in a computer-readable non-transitory tangible storage medium as an instruction that is executed by a computer.

Hereinafter, characteristic configurations extracted from each of the embodiments described above will be described.

### Configuration 1

A circuit board (36, 46) to be used for a battery monitoring system (2) configured to monitor a battery condition of a battery unit (20, 21, 22) includes a wireless antenna (34, 44), a wireless unit (32, 42) configured to perform wireless communication through the wireless antenna to transmit or receive the battery condition, and a connecting conductor (38, 48) configured to be connectable to an electrical path between the wireless unit and the wireless antenna and configured to allow an inspection terminal (38a, 48a) to be electrically connected thereto.

### Configuration 2

The circuit board of the battery monitoring system according to Configuration 1 includes a high-voltage region (36a, 46a), and a low-voltage region (36b, 46b). The connecting conductor is disposed in one of the high- and low-voltage regions. One or more electronic components are disposed between the connecting conductor and the other of the high- and low-voltage regions.

### Configuration 3

The circuit board of the battery monitoring system according to Configuration 1 or 2 includes a high-voltage region (36a, 46a), and a low-voltage region (36b, 46b). A front-end unit (33, 43) is disposed in the electrical path between the wireless unit and the wireless antenna, and the connecting conductor is disposed in one of the high- and low-voltage regions. Any of electronic components (61a to 61e) included in the front-end unit is disposed between the connecting conductor and the other of the high- and low-voltage regions.

### Configuration 4

In the circuit board of the battery monitoring system according to Configuration 3, the front-end unit is arranged between the connecting conductor and a boundary region (36c, 46c), the boundary region being arranged between the high-voltage region and the low-voltage region.

### Configuration 5

In the circuit board of the battery monitoring system according to any of Configurations 1 to 4, the battery unit is an assembled battery (20) including a combination of a plurality of unit batteries (22). The battery monitoring system includes a battery monitoring device (30) configured to monitor, as a monitoring target, either (i) each unit battery or (ii) a battery block (21) including a combination of selected ones of the unit batteries, and detect, as the battery condition, a condition of the monitoring target. The battery monitoring system includes a battery control device (40) configured to manage the assembled battery based on the condition of the monitoring target detected by the battery monitoring device. The circuit board is used for the battery control device. The connecting conductor (48) is disposed in the low-voltage region (46b) of the circuit board. A measurement unit (45) is disposed in the high-voltage region (46a) and configured to measure a condition of the assembled battery.

### Configuration 6

In the circuit board of the battery monitoring system according to any of Configurations 1 to 4, the battery unit is an assembled battery (20) including a combination of a plurality of unit batteries (22). The battery monitoring system includes a battery monitoring device (30) configured to monitor, as a monitoring target, either (i) each unit battery or (ii) a battery block (21) comprising a combination of selected ones of the unit batteries, and detect, as the battery condition, a condition of the monitoring target. The battery monitoring system includes a battery control device (40) configured to manage the assembled battery based on the condition of the monitoring target detected by the battery monitoring device. The circuit board is used for the battery monitoring device. The connecting conductor (38) is disposed in the high-voltage region (36a) of the circuit board. The circuit board further comprising a fastening member (37A to 37D provided in the low-voltage region (36b) and used to fasten the circuit board to a ground member (50) and electrically connect between the ground member and an electrical path in the low-voltage region. The connecting conductor is disposed farther from the fastening member than one of the electronic component located closest to the fastening member.

### Configuration 7

The circuit board of the battery monitoring system according to Configuration 6 further includes an equalization circuit (35) mounted to the circuit board and configured to equalize voltages of the respective unit batteries. One of the wireless antenna and the equalization circuit is disposed closer to an outer edge portion of the circuit board and the other of the wireless antenna and the equalization circuit is disposed closer to a central portion of the circuit board.

### Configuration 8

The circuit board of the battery monitoring system according to Configuration 6 or 7 further includes a monitoring unit (31) mounted to the circuit board and configured to detect the condition of the monitoring target. The connecting conductor is disposed between the monitoring unit and a high-frequency circuit comprised of at least one of the wireless unit and the wireless antenna.

### Configuration 9

The circuit board of the battery monitoring system according to any of Configurations 6 to 8, further includes a monitoring unit (31) mounted to the circuit board and configured to detect the condition of the monitoring target, and a slit (65) formed in the circuit board and arranged between the monitoring unit and a high-frequency circuit comprised of at least one of the wireless unit and the wireless antenna.

### Configuration 10

The circuit board of the battery monitoring system according to any of Configurations 6 to 9 further includes a monitoring unit (31) mounted to the circuit board and configured to detect the condition of the monitoring target, and a detection line (66) soldered to the circuit board and configured to be connected to the monitoring target.

### Configuration 11

The circuit board of the battery monitoring system according to any of Configurations 1 to 10 further includes one or more fastening members (37A to 37D, 47A to 47D) provided at an outer edge portion of the circuit board and used to fasten the circuit board. The connecting conductor is disposed closer to an inner side of the circuit board than the one or more fastening members.

### Configuration 12

In the circuit board of the battery monitoring system according to Configuration 11, the fastening members are provided at the outer edge portion of the circuit board, and the connecting conductor or the wireless antenna is disposed to the circuit board so as to avoid a straight-line region connecting between any pair of the fastening members.

### Configuration 13

In the circuit board of the battery monitoring system according to Configuration 11 or 12, the circuit board has a polygonal shape defining a plurality of sides, the wireless antenna is disposed adjacent to a selected side among the sides of the circuit board, and one of the one or more fastening members located closest to the wireless antenna is disposed adjacent to one of the remaining sides other than the selected side.

### Configuration 14

In the circuit board of the battery monitoring system according to any of Configurations 11 to 13, the circuit board has a polygonal shape defining a plurality of sides, one of the one or more fastening members located closest to the wireless antenna is provided at an outer edge portion of the circuit board so as to be disposed adjacent to a selected side among the sides of the circuit board, and the connecting conductor is disposed adjacent to one side of the circuit board opposite to the selected side of the circuit board or disposed closer to a middle of the circuit board than the fastening member located closest to the wireless antenna.

### Configuration 15

In the circuit board of the battery monitoring system according to any of Configurations 1 to 14, the circuit board is to be housed in a housing (50), an outer edge portion of the circuit board is disposed to be opposite to an inner wall of the housing, and the connecting conductor is disposed closer to an inner side of the circuit board than the wireless antenna so as to be located farther from the inner wall of the housing than the wireless antenna while the circuit board is housed in the housing.

### Configuration 16

In the circuit board of the battery monitoring system according to any of Configurations 1 to 15, the connecting conductor is arranged outside a predetermined range centered on a direction in which a radio wave radiated from the wireless antenna has greatest radiant intensity.

### Configuration 17

In the circuit board of the battery monitoring system according to any of Configurations 1 to 16, the battery unit is an assembled battery (20) including a combination of a plurality of unit batteries (22). The circuit board further includes an equalization circuit (30) mounted to the circuit board and configured to equalize voltages of the respective unit batteries. The equalization circuit is disposed closer to the connecting conductor than the wireless unit.

### Configuration 18

In the circuit board of the battery monitoring system according to any of Configurations 1 to 17, the circuit board has opposing first and second surfaces, the wireless unit and the connecting conductor are disposed on the first surface, and the battery unit is an assembled battery (20) including a combination of a plurality of unit batteries (22). The circuit board further includes an equalization circuit (35) mounted to the circuit board and configured to equalize voltages of the respective unit batteries. The equalization circuit is disposed on the second surface of the circuit board.

### Configuration 19

In the circuit board of the battery monitoring system according to any of Configurations 1 to 18, the connecting conductor is sealed using an insulating material (62).

### Configuration 20

In the circuit board of the battery monitoring system according to any of Configurations 1 to 19, the wireless antenna or the connecting conductor is disposed to face a metal part constituting a housing when the circuit board is housed in the housing or a casing of the battery unit.

### Configuration 21

In the circuit board of the battery monitoring system according to any of Configurations 1 to 20, the battery unit is an assembled battery (20) including a combination of a plurality of unit batteries (22), and the battery unit includes a cooling blower (63) that generates wind. The circuit board further includes an equalization circuit (35) mounted to the circuit board and configured to equalize voltages of the respective unit batteries. The equalization circuit is disposed on a downstream of the wireless antenna and the connecting conductor in a path of the wind generated by the cooling blower of the battery unit.

### Configuration 22

A power supply system (11) includes a battery monitoring device (30) including a first circuit board (36) and configured to detect a battery condition of a battery unit (20, 21, 22), and a battery control device (40) including a second circuit board (46) and configured to wirelessly communicate with the battery monitoring device to obtain the battery condition detected by the battery monitoring device and manage the battery unit based on the battery condition. Each of the first circuit board and the second circuit board has opposing first and second ends. The power supply system includes a wireless antenna (32, 42) mounted to each of the first and second circuit boards, and a wireless unit (31, 41) mounted to each of the first and second circuit boards and configured to perform wireless communication through the wireless antenna to transmit or receive the battery condition. The power supply system includes a connecting conductor (38, 48) mounted to each of the first and second circuit boards and configured to be connectable to an electrical path between the wireless unit and the wireless antenna and configured to allow an inspection terminal (38a, 48a) to be electrically connected thereto, and a connector (31a, 41a) attached to one of the first and second ends of each of the first and second circuit boards. The connector (41a) of the second circuit board is configured to be connectable to an external device (14) by wire. The wireless antenna of the second circuit board is disposed adjacent to the second end of the second circuit board of the battery control device.

### Configuration 23

In the power supply system according to Configuration 22, the first circuit board of the battery monitoring device is disposed adjacent to the second side of the second circuit board of the battery control device which the wireless antenna is disposed adjacent to.

### Configuration 24

In the power supply system according to Configuration 22 or 23, the wireless antenna of each of the first and second circuit boards is a directional antenna and has high radiant intensity of a radio wave in a predetermined radiation direction, and the connector of each of the first and second circuit boards is disposed in a direction opposite to the radiation direction with respect to the wireless antenna of the corresponding one of the first and second circuit boards.

### Configuration 25

In the power supply system according to any of Configurations 22 to 24, each of the first and second circuit boards is formed in a polygonal shape a plurality of sides. The power supply system further includes a fastening member (137B, 137D) provided for each of the first and second circuit boards and protruded from a selected side of the corresponding one of the first and second circuit boards. The wireless antenna of each of the first and second circuit boards is mounted on an outer edge portion of the corresponding one of the first and second circuit boards so as to be disposed adjacent to one of the remaining sides of the corresponding one of the first and second circuit boards other than the selected side.

### Configuration 26

A power supply control system (1) includes a battery unit (20, 21, 22) and a power supply system (11) including a battery monitoring device (30) and a battery control device (40). The battery monitoring device includes a first circuit board (36) and is configured to detect a battery condition of the battery unit. The battery control device includes a second circuit board (46) and is configured to wirelessly communicate with the battery monitoring device to obtain the battery condition detected by the battery monitoring device and manage the battery unit based on the battery condition. The power supply control system includes a power converter (12, 15) configured to be connected to the power supply system, the power converter including a switching element configured to convert power from the power supply system or switch between electrical connection and electrical disconnection of the power supply system. Each of the first circuit board and the second circuit board includes a wireless antenna (32, 42) mounted thereto, and a wireless unit (31, 41) mounted thereto and configured to perform wireless communication through the wireless antenna to transmit or receive the battery condition. Each of the first circuit board and the second circuit board includes a connecting conductor (38, 48) mounted thereto and configured to be connectable to an electrical path between the wireless unit and the wireless antenna and configured to allow an inspection terminal (38a, 48a) to be electrically connected to the connecting conductor. Each of the first circuit board and the second circuit board includes a front-end unit (33, 43) mounted thereto and disposed in the electrical path between the wireless unit and the wireless antenna. At least one of the first circuit board and the second circuit board is connected to a busbar (16) configured to connect the battery unit and an electrical load (13). The power converter is connected to a ground member and configured to discharge noise generated by on/off control of the switching element to the ground member, thus decreasing intensity of noise flowing from the busbar to the front-end unit of the at least one of the first circuit board and the second circuit board to a value less than or equal to a current flowing through the front-end unit or a voltage across the front-end unit.

The present disclosure is described in compliance with the Example, but it should be understood that the present disclosure is not limited to the Example and the structures. The present disclosure encompasses even various modification examples and modifications within the equivalent scope. In addition, various combinations and forms, and further other combinations and forms including only one, more, or fewer of the elements also fall within the scope and the spirit of the present disclosure.

1. A circuit board to be used for a battery monitoring system configured to monitor a battery condition of a battery unit, the circuit board comprising:
a wireless antenna;
a wireless unit configured to perform wireless communication through the wireless antenna to transmit or receive the battery condition; and
a connecting conductor configured to be connectable to an electrical path between the wireless unit and the wireless antenna and configured to allow an inspection terminal to be electrically connected thereto.

2. The circuit board of the battery monitoring system according to claim 1, comprising:
a high-voltage region; and
a low-voltage region, wherein
the connecting conductor is disposed in one of the high- and low-voltage regions; and
one or more electronic components are disposed between the connecting conductor and the other of the high- and low-voltage regions.

3. The circuit board of the battery monitoring system according to claim 1, comprising:
a high-voltage region; and
a low-voltage region, wherein
a front-end unit is disposed in the electrical path between the wireless unit and the wireless antenna;
the connecting conductor is disposed in one of the high- and low-voltage regions; and
any of electronic components included in the front-end unit is disposed between the connecting conductor and the other of the high- and low-voltage regions.

4. The circuit board of the battery monitoring system according to claim 3, wherein
the front-end unit is arranged between the connecting conductor and a boundary region, the boundary region being arranged between the high-voltage region and the low-voltage region.

5. The circuit board of the battery monitoring system according to claim 2, wherein
the battery unit is an assembled battery including a combination of a plurality of unit batteries;
the battery monitoring system includes:
a battery monitoring device configured to:
monitor, as a monitoring target, either (i) each unit battery or (ii) a battery block comprising a combination of selected ones of the unit batteries; and
detect, as the battery condition, a condition of the monitoring target; and
a battery control device configured to manage the assembled battery based on the condition of the monitoring target detected by the battery monitoring device;
the circuit board is used for the battery control device;
the connecting conductor is disposed in the low-voltage region of the circuit board; and
a measurement unit is disposed in the high-voltage region and configured to measure a condition of the assembled battery.

6. The circuit board of the battery monitoring system according to claim 2, wherein
the battery unit is an assembled battery including a combination of a plurality of unit batteries;
the battery monitoring system includes:
a battery monitoring device configured to:
monitor, as a monitoring target, either (i) each unit battery or (ii) a battery block comprising a combination of selected ones of the unit batteries; and
detect, as the battery condition, a condition of the monitoring target; and
a battery control device configured to manage the assembled battery based on the condition of the monitoring target detected by the battery monitoring device; and
the circuit board is used for the battery monitoring device;
the connecting conductor is disposed in the high-voltage region of the circuit board,
the circuit board further comprising a fastening member provided in the low-voltage region and used to fasten the circuit board to a ground member and electrically connect between the ground member and an electrical path in the low-voltage region,
the connecting conductor being disposed farther from the fastening member than one of the electronic component located closest to the fastening member.

7. The circuit board of the battery monitoring system according to claim 6, further comprising an equalization circuit mounted to the circuit board and configured to equalize voltages of the respective unit batteries, wherein
one of the wireless antenna and the equalization circuit is disposed closer to an outer edge portion of the circuit board and the other of the wireless antenna and the equalization circuit is disposed closer to a central portion of the circuit board.

8. The circuit board of the battery monitoring system according to claim 6, further comprising a monitoring unit mounted to the circuit board and configured to detect the condition of the monitoring target, wherein
the connecting conductor is disposed between the monitoring unit and a high-frequency circuit comprised of at least one of the wireless unit and the wireless antenna.

9. The circuit board of the battery monitoring system according to claim 6, further comprising:
a monitoring unit mounted to the circuit board and configured to detect the condition of the monitoring target; and
a slit formed in the circuit board and arranged between the monitoring unit and a high-frequency circuit comprised of at least one of the wireless unit and the wireless antenna.

10. The circuit board of the battery monitoring system according to claim 6, further comprising:
a monitoring unit mounted to the circuit board and configured to detect the condition of the monitoring target; and
a detection line soldered to the circuit board and configured to be connected to the monitoring target.

11. The circuit board of the battery monitoring system according to claim 2, further comprising:
one or more fastening members provided at an outer edge portion of the circuit board and used to fasten the circuit board, wherein
the connecting conductor is disposed closer to an inner side of the circuit board than the one or more fastening members.

12. The circuit board of the battery monitoring system according to claim 11, wherein
the fastening members are provided at the outer edge portion of the circuit board; and
the connecting conductor or the wireless antenna is disposed to the circuit board so as to avoid a straight-line region connecting between any pair of the fastening members.

13. The circuit board of the battery monitoring system according to claim 11, wherein
the circuit board has a polygonal shape defining a plurality of sides;
the wireless antenna is disposed adjacent to a selected side among the sides of the circuit board; and
one of the one or more fastening members located closest to the wireless antenna is disposed adjacent to one of the remaining sides other than the selected side.

14. The circuit board of the battery monitoring system according to claim 11, wherein
the circuit board has a polygonal shape defining a plurality of sides;
one of the one or more fastening members located closest to the wireless antenna is provided at an outer edge portion of the circuit board so as to be disposed adjacent to a selected side among the sides of the circuit board; and
the connecting conductor is disposed adjacent to one side of the circuit board opposite to the selected side of the circuit board or disposed closer to a middle of the circuit board than the fastening member located closest to the wireless antenna.

15. The circuit board of the battery monitoring system according to claim 1, wherein
the circuit board is to be housed in a housing;
an outer edge portion of the circuit board is disposed to be opposite to an inner wall of the housing; and
the connecting conductor is disposed closer to an inner side of the circuit board than the wireless antenna so as to be located farther from the inner wall of the housing than the wireless antenna while the circuit board is housed in the housing.

16. The circuit board of the battery monitoring system according to claim 1, wherein
the connecting conductor is arranged outside a predetermined range centered on a direction in which a radio wave radiated from the wireless antenna has greatest radiant intensity.

17. The circuit board of the battery monitoring system according to claim 1, wherein the battery unit is an assembled battery including a combination of a plurality of unit batteries,
the circuit board further comprising:
an equalization circuit mounted to the circuit board and configured to equalize voltages of the respective unit batteries,
the equalization circuit being disposed closer to the connecting conductor than the wireless unit.

18. The circuit board of the battery monitoring system according to claim 1, wherein
the circuit board has opposing first and second surfaces;
the wireless unit and the connecting conductor are disposed on the first surface; and
the battery unit is an assembled battery including a combination of a plurality of unit batteries,
the circuit board further comprising:
an equalization circuit mounted to the circuit board and configured to equalize voltages of the respective unit batteries,
the equalization circuit being disposed on the second surface of the circuit board.

19. The circuit board of the battery monitoring system according to claim 1, wherein the connecting conductor is sealed using an insulating material.

20. The circuit board of the battery monitoring system according to claim 1, wherein
the wireless antenna or the connecting conductor is disposed to face a metal part constituting a housing when the circuit board is housed in the housing or a casing of the battery unit.

21. The circuit board of the battery monitoring system according to claim 1, wherein
the battery unit is an assembled battery including a combination of a plurality of unit batteries; and
the battery unit includes a cooling blower that generates wind,
the circuit board further comprising:
an equalization circuit mounted to the circuit board and configured to equalize voltages of the respective unit batteries,
the equalization circuit being disposed on a downstream of the wireless antenna and the connecting conductor in a path of the wind generated by the cooling blower of the battery unit.

22. A power supply system comprising:
a battery monitoring device including a first circuit board and configured to detect a battery condition of a battery unit;
a battery control device including a second circuit board and configured to wirelessly communicate with the battery monitoring device to obtain the battery condition detected by the battery monitoring device and manage the battery unit based on the battery condition,
each of the first circuit board and the second circuit board having opposing first and second ends;
a wireless antenna mounted to each of the first and second circuit boards;
a wireless unit mounted to each of the first and second circuit boards and configured to perform wireless communication through the wireless antenna to transmit or receive the battery condition;
a connecting conductor mounted to each of the first and second circuit boards and configured to be connectable to an electrical path between the wireless unit and the wireless antenna and configured to allow an inspection terminal to be electrically connected thereto; and
a connector attached to one of the first and second ends of each of the first and second circuit boards,
the connector of the second circuit board being configured to be connectable to an external device by wire,
the wireless antenna of the second circuit board being disposed adjacent to the second end of the second circuit board of the battery control device.

23. The power supply system according to claim 22, wherein
the first circuit board of the battery monitoring device is disposed adjacent to the second side of the second circuit board of the battery control device which the wireless antenna is disposed adjacent to.

24. The power supply system according to claim 22, wherein
the wireless antenna of each of the first and second circuit boards is a directional antenna and has high radiant intensity of a radio wave in a predetermined radiation direction; and
the connector of each of the first and second circuit boards is disposed in a direction opposite to the radiation direction with respect to the wireless antenna of the corresponding one of the first and second circuit boards.

25. The power supply system according to claim 22, wherein
each of the first and second circuit boards is formed in a polygonal shape a plurality of sides,
the power supply system further comprising:
a fastening member provided for each of the first and second circuit boards and protruded from a selected side of the corresponding one of the first and second circuit boards,
the wireless antenna of each of the first and second circuit boards being mounted on an outer edge portion of the corresponding one of the first and second circuit boards so as to be disposed adjacent to one of the remaining sides of the corresponding one of the first and second circuit boards other than the selected side.

26. A power supply control system comprising:
a battery unit;
a power supply system including a battery monitoring device and a battery control device,
the battery monitoring device including a first circuit board and being configured to detect a battery condition of the battery unit,
the battery control device including a second circuit board and being configured to wirelessly communicate with the battery monitoring device to obtain the battery condition detected by the battery monitoring device and manage the battery unit based on the battery condition; and
a power converter configured to be connected to the power supply system, the power converter including a switching element configured to convert power from the power supply system or switch between electrical connection and electrical disconnection of the power supply system, wherein
each of the first circuit board and the second circuit board comprises:
a wireless antenna mounted thereto;
a wireless unit mounted thereto and configured to perform wireless communication through the wireless antenna to transmit or receive the battery condition;
a connecting conductor mounted thereto and configured to be connectable to an electrical path between the wireless unit and the wireless antenna and configured to allow an inspection terminal to be electrically connected to the connecting conductor; and
a front-end unit mounted thereto and disposed in the electrical path between the wireless unit and the wireless antenna;
at least one of the first circuit board and the second circuit board is connected to a busbar configured to connect the battery unit and an electrical load; and
the power converter is connected to a ground member and configured to discharge noise generated by on/off control of the switching element to the ground member, thus decreasing intensity of noise flowing from the busbar to the front-end unit of the at least one of the first circuit board and the second circuit board to a value less than or equal to a current flowing through the front-end unit or a voltage across the front-end unit.
